(19) United States
(12) Patent Application Publication
(10) Pub. No.: US 2026/0282871 A1
(43) Pub. Date: Sep. 17, 2026

(54) Dual Guard Ring Design for Through Via

(71) Applicant: Taiwan Semiconductor Manufacturing Company, Ltd., Hsin-Chu (TW)

(72) Inventors: Ke-Gang WEN, Hsinchu (TW); Yu-Bey WU, Hsinchu (TW); Chih Hsin YANG, Hsinchu County (TW); Chih-Pin CHIU, Hsinchu (TW); Liang-Wei WANG, Hsinchu City (TW)

(21) Appl. No.: 19/337,238

(22) Filed: Sep. 23, 2025

Related U.S. Application Data
(60) Provisional application No. 63/770,597, filed on Mar. 12, 2025.

(51) Int. Cl. H10W 20/20; H10W 20/00; H10W 90/00; H10W 90/20

(52) U.S. Cl. CPC H10W 20/217; H10W 20/023; H10W 20/2125; H10W 20/213; H10W 90/297; H10W 90/792

(57) ABSTRACT

A dual guard ring structure includes a first guard ring (e.g., a primary guard ring) and a second guard ring (e.g., a secondary guard ring). The first guard ring discrete from and laterally adjacent to the second guard ring. The second guard ring overlaps a gap in the first guard ring, such that the dual guard ring structure overlaps a sidewall of a through via along the dual guard ring structure's entire height. In some embodiments, the first guard ring and the second guard ring are an outer guard ring and an inner guard ring, respectively. In some embodiments, the first guard ring and the second guard ring are an inner guard ring and an outer guard ring, respectively. In some embodiments, an outer guard ring and an inner guard ring of the dual guard ring structure are formed by both the first guard ring and the second guard ring.

This is a non-provisional application of and claims benefit of U.S. Provisional Patent Application Ser. No. 63/770,597, filed Mar. 12, 2025, the entire disclosure of which is incorporated herein by reference.

### BACKGROUND

The semiconductor integrated circuit (IC) industry has experienced rapid growth. Continuing advances in semiconductor manufacturing processes have resulted in integrated circuits (“ICs”) having semiconductor devices with finer features and/or higher degrees of integration. Functional density (i.e., the number of interconnected devices per IC chip area) has generally increased while feature size (i.e., the smallest component that can be created using a fabrication process) has decreased. This scaling-down process has generally provided benefits by increasing production efficiency and lowering associated costs.

Advanced IC packaging technologies have been developed to further reduce density and/or improve performance of ICs. For example, IC packaging has evolved, such that multiple ICs may be vertically stacked in three-dimensional (“3D”) packages, or 2.5D packages (which use an interposer). Through via (also referred to as through-silicon via (TSV)) is one technique for connecting stacked ICs. Such techniques sometimes implement protective structures and/or shielding structures, such as guard rings, to improve TSV reliability and integrity. Design improvements in protective structures and/or shielding structures are needed.

### BRIEF DESCRIPTION OF THE DRAWINGS

The present disclosure is best understood from the following detailed description when read with the accompanying figures. It is emphasized that, in accordance with standard practice in the industry, various features are not drawn to scale and are used for illustration purposes only. Dimensions of the various features may be arbitrarily increased or reduced for clarity of discussion.

FIG. 1A is a cross-sectional view of a stacked chip structure, in portion or entirety, having an improved guard ring design, according to various aspects of the present disclosure.

FIG. 1B is a cross-sectional view of the stacked chip structure of FIG. 1, in portion or entirety, and electrical paths thereof, according to various aspects of the present disclosure.

FIG. 2 is an enlarged, cross-sectional view of a portion of the stacked chip structure of FIG. 1 according to various aspects of the present disclosure.

FIG. 3 is an enlarged, cross-sectional view of another portion of the stacked chip structure of FIG. 1A according to various aspects of the present disclosure.

FIG. 4 and FIG. 5 are plan views of the portion of the stacked chip structure of FIG. 3 according to various aspects of the present disclosure.

FIG. 6 is an enlarged, cross-sectional view of the portion of the stacked chip structure of FIG. 3, which depicts another through via configuration that may be implemented in the stacked chip structure, according to various aspects of the present disclosure.

FIGS. 7A-7G are top views of through vias, in portion or entirety, and FIGS. 8A-8G are top views of guard rings, in portion or entirety, that may be implemented in the stacked chip structure of FIG. 1, according to various aspects of the present disclosure.

FIG. 9A is an enlarged, cross-sectional view of the portion of the stacked chip structure of FIG. 3 having a different through via contact configuration, according to various aspects of the present disclosure, and FIG. 9B is a plan view of the portion of stacked chip structure of FIG. 9A, according to various aspects of the present disclosure.

FIG. 10 is a plan view of the portion of the stacked chip structure of FIG. 9A of yet another through via contact configuration, according to various aspects of the present disclosure.

FIGS. 11-15 are enlarged, cross-sectional views of the portion of stacked chip structure of FIG. 3 depicting different guard ring configurations having the improved guard ring design, according to various aspects of the present disclosure.

FIGS. 16A-16L are fragmentary cross-sectional views of a device structure, in portion or entirety, at various fabrication stages of forming a through via and a guard ring having improved guard ring design, according to various aspects of the present disclosure.

FIG. 17 is a flow chart of a method, in portion or entirety, for fabricating a guard ring and a through via, such as that of FIG. 3, according to various aspects of the present disclosure.

### DETAILED DESCRIPTION

The present disclosure relates generally to integrated circuit (IC) and/or semiconductor packaging, and more particularly, to guard rings for through vias.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact and may also include embodiments in which additional features may be formed between the first feature and the second feature, such that the first feature and the second feature may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−20% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. In another example, two features described as having “substantially the same” dimension and/or “substantially” oriented in a particular direction and/or configuration (e.g., “substantially parallel”) encompasses dimension differences between the two features and/or slight orientation variances of the two features from the exact specified orientation that may arise inherently, but not intentionally, from manufacturing tolerances associated with fabricating the two features. Still further, the present disclosure may repeat reference numerals and/or letters in the various examples. This repetition is for the purpose of simplicity and clarity and does not in itself dictate a relationship between the various embodiments and/or configurations described herein.

Advanced IC packaging technologies have been developed to further reduce density and/or improve performance of integrated circuits (ICs), which are incorporated into many electronic devices. For example, IC packaging has evolved, such that multiple ICs may be vertically stacked in three-dimensional (“3D”) packages or 2.5D packages (e.g., packages that implement an interposer). Through via (also referred to as through-silicon via (TSV)) is one technique for connecting stacked ICs. For example, where a first chip is stacked vertically over a second chip, a TSV may be formed that extends vertically through the first chip to the second chip, where the TSV electrically and/or physically connects a first conductive structure (e.g., first wiring) of the first chip to a second conductive structure (e.g., second wiring) of the second chip. The TSV is an electrically conductive structure, such as a copper structure, and may extend through a portion or an entirety of the first chip to the second chip.

A guard ring is often formed around the TSV to protect the TSV, improve TSV performance, improve TSV structural stability, shield and/or reduce TSV-induced noise that can negatively impact the first chip and/or the second chip, or combinations thereof. The guard ring may be formed when forming a back-end-of-line (BEOL) structure of the first chip, such as first wiring of the first chip. The first wiring (e.g., a frontside multilayer interconnect (MLI) thereof) may be disposed over and connected to a first device substrate of the first chip and facilitate operation and/or electrical communication of devices and/or structures of the first device substrate. The TSV may be formed after forming the BEOL structure. For example, the TSV may be formed by a TSV backside fabrication process, which may include flipping over the first chip, etching through the first device substrate (e.g., from backside to frontside thereof) and a dielectric layer of the BEOL structure (e.g., in an area defined by the guard) to form a TSV trench, and filling the TSV trench with an electrically conductive material. The first chip may then be bonded and/or attached to the second chip, and the TSV may be electrically connected to the second chip, such as to a BEOL structure of the second chip. The BEOL structure of the second chip may be disposed over and connected to a second device substrate of the second chip, and the BEOL structure of the second chip may facilitate operation and/or electrical communication of devices and/or structures of the second device substrate.

The present disclosure proposes a dual guard ring design that may improve device reliability and/or device performance, for example, by preventing and/or reducing damage to device structures and/or device features during through via fabrication. In some embodiments, a dual guard ring structure includes a first guard ring (e.g., a primary guard) and a second guard ring (e.g., a secondary guard ring). The first guard ring is separate from and not connected to the second guard ring, and the second guard ring is laterally spaced from the first guard ring. The second guard ring overlaps a gap in the first guard ring, such that the dual guard ring structure overlaps a sidewall of a through via along the dual guard ring structure's entire height. Various configurations of the first guard ring and the second guard ring are contemplated by the present disclosure. In some embodiments, the first guard ring and the second guard ring are an outer guard ring and an inner guard ring, respectively. In some embodiments, the first guard ring and the second guard ring are an inner guard ring and an outer guard ring, respectively. In some embodiments, an outer guard ring and an inner guard ring of the dual guard ring structure are formed by both the first guard ring and the second guard ring. The present disclosure further contemplates the second guard ring being positioned at any level of the dual guard ring structure depending on position of the gap(s) in the first guard ring. Dual guard ring structures disclosed herein may prevent and/or reduce moisture attack on low-k dielectric materials and/or metal materials, such as those associated with multilayer interconnect structures, thereby improving device integrity. Details of the proposed dual guard ring design, TSV design corresponding therewith, and/or fabrication thereof are described herein. Different embodiments may have different advantages, and no particular advantage is required of any embodiment.

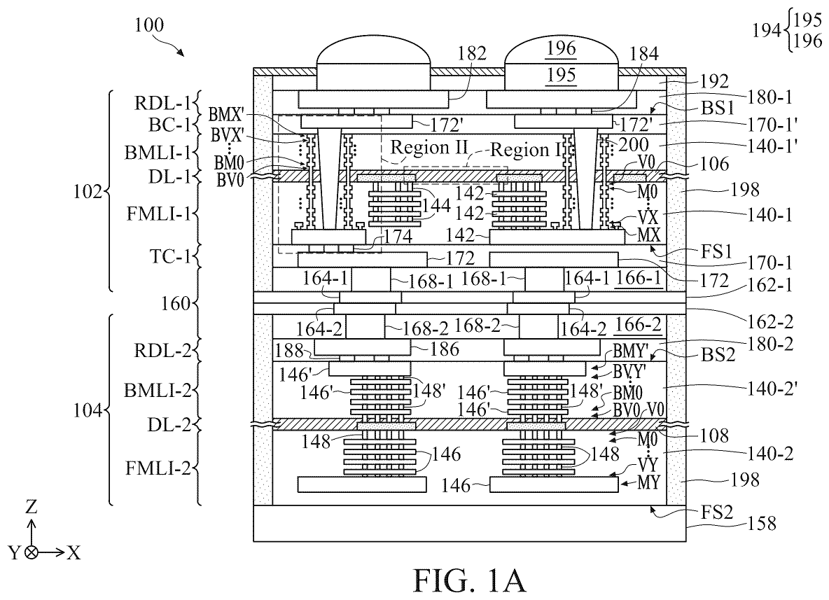

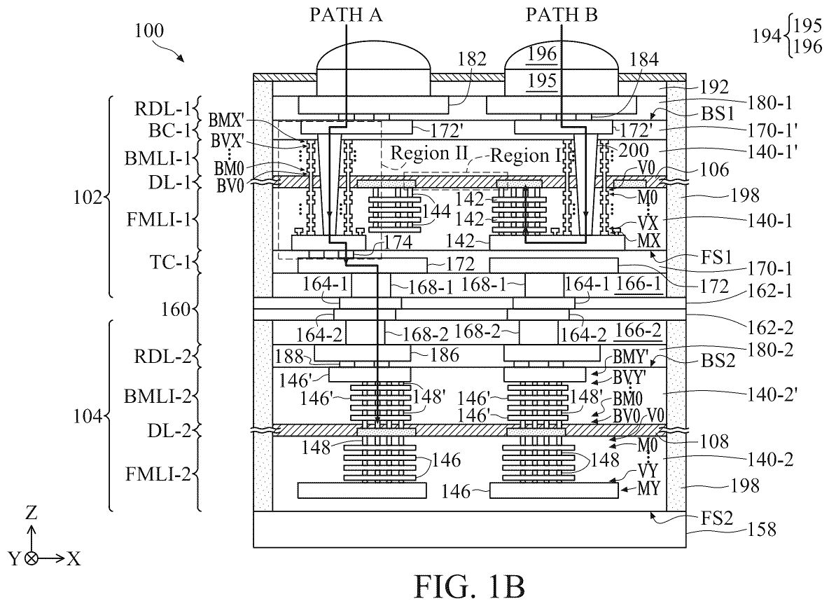

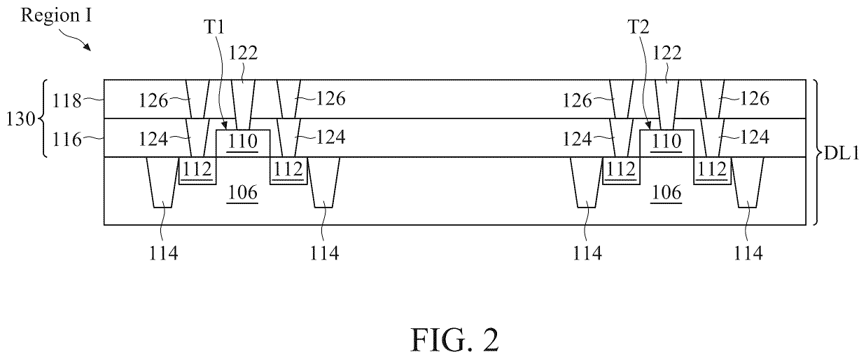

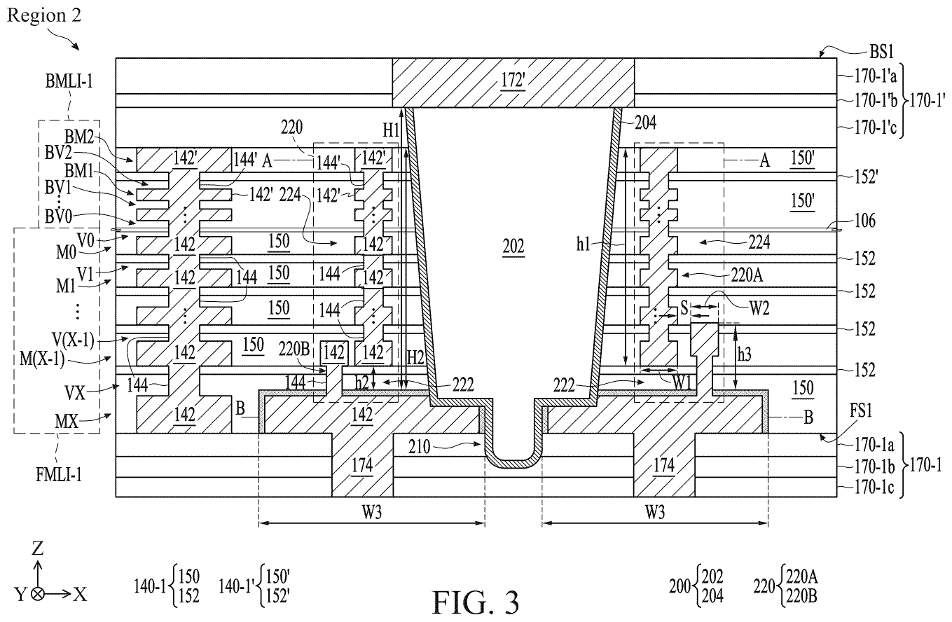

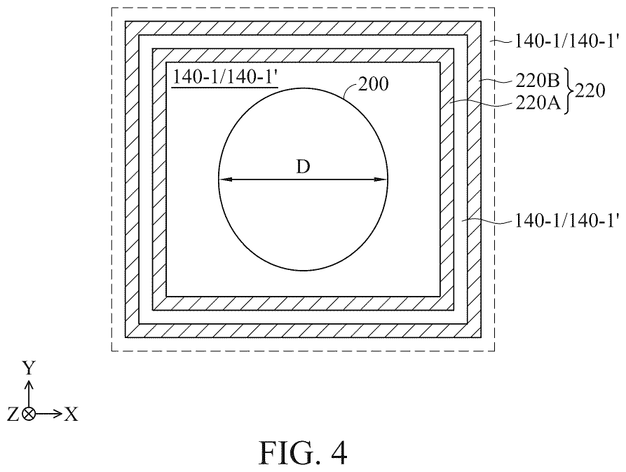

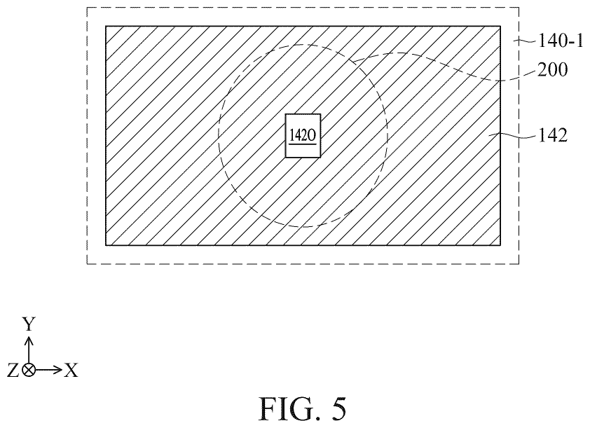

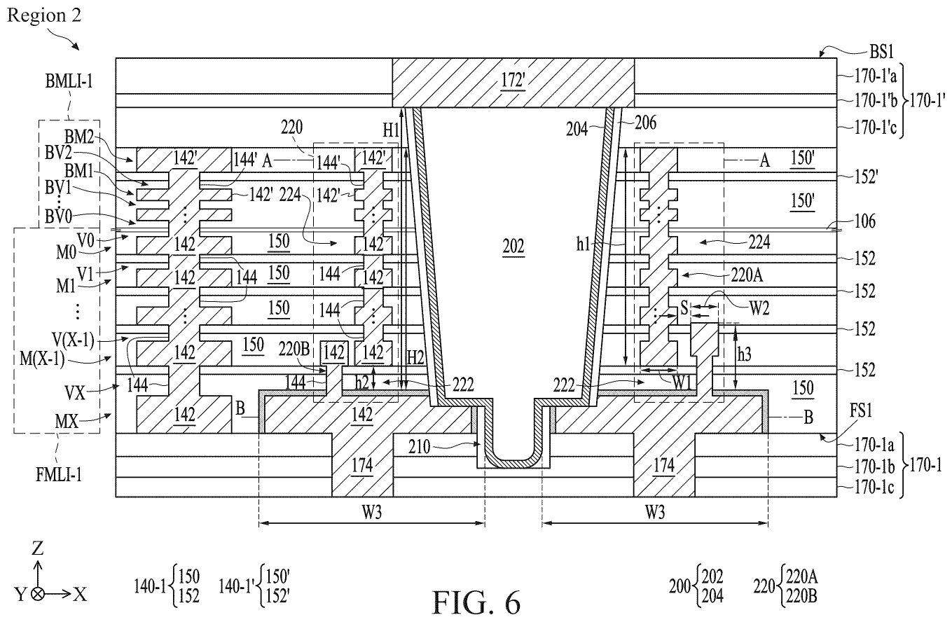

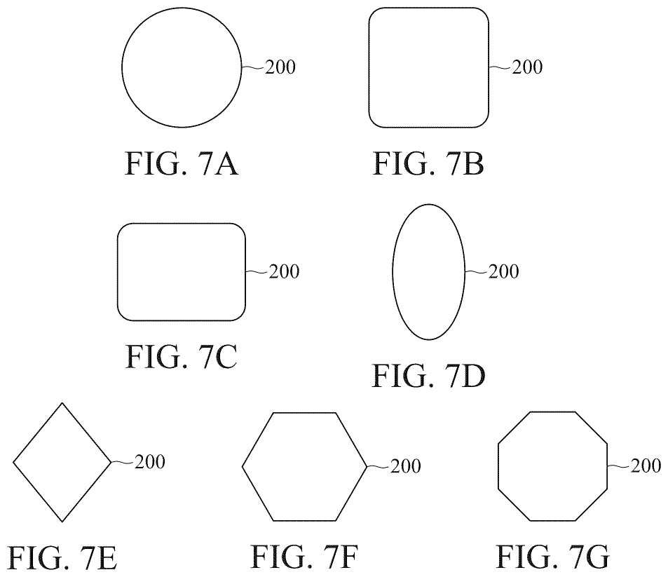

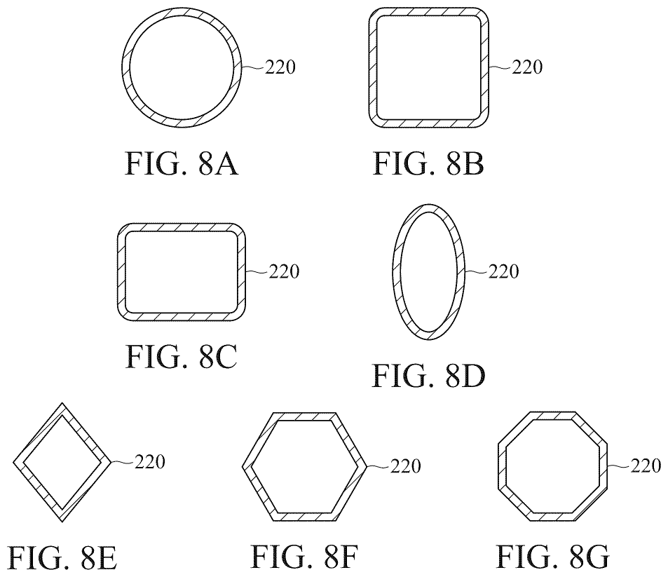

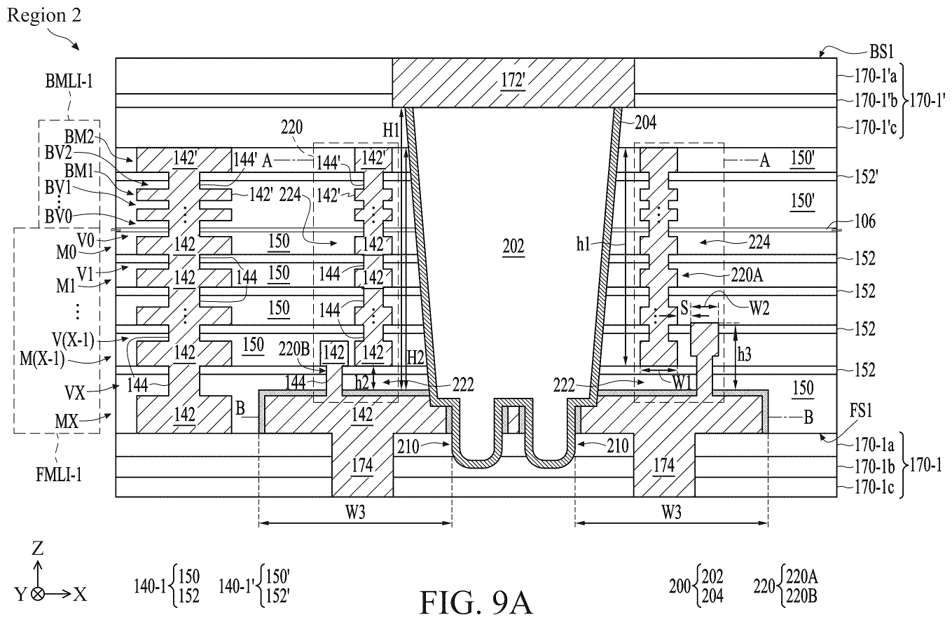

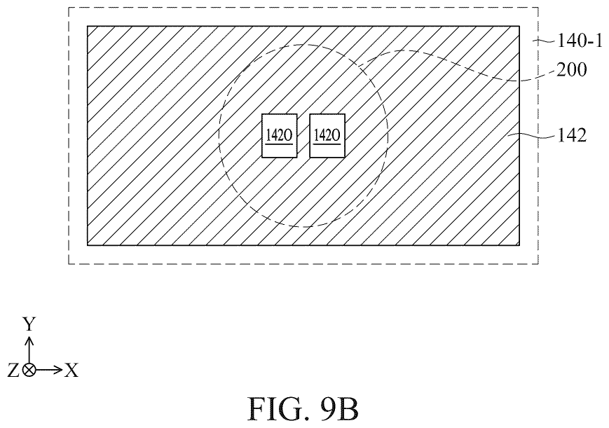

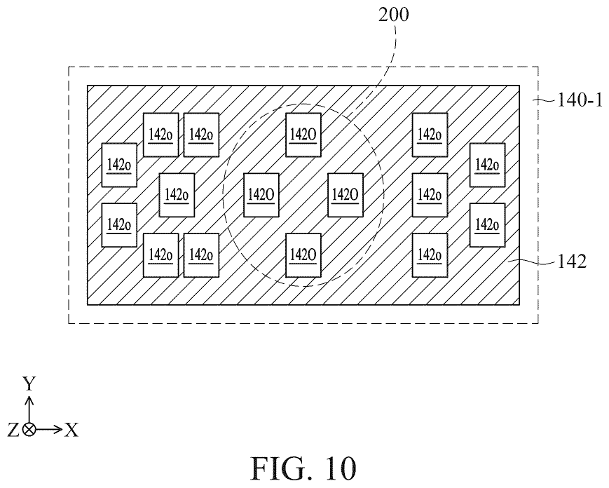

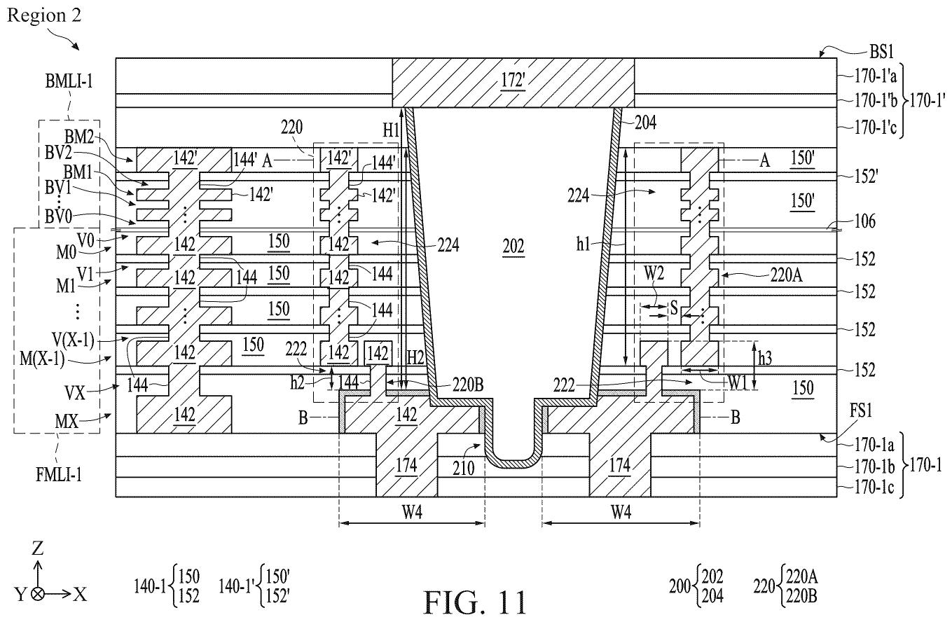

FIG. 1A is a cross-sectional view of a stacked chip structure 100, in portion or entirety, having an improved guard ring design, according to various aspects of the present disclosure. FIG. 1B is a cross-sectional view of stacked chip structure 100, in portion or entirety, illustrating various electrical paths thereof, according to various aspects of the present disclosure. FIG. 2 is an enlarged, cross-sectional view of a portion of stacked chip structure 100, according to various aspects of the present disclosure. FIG. 3 is an enlarged, cross-sectional view of another portion of stacked chip structure 100, according to various aspects of the present disclosure. FIG. 4 is a top view of the portion of stacked chip structure 100 of FIG. 3 along line A-A thereof, according to various aspects of the present disclosure. FIG. 5 is a top view of the portion of stacked chip structure 100 of FIG. 3 along line B-B thereof, according to various aspects of the present disclosure. FIG. 6 is an enlarged, cross-sectional view of the portion of stacked chip structure 100 of FIG. 3 having a different through via configuration, according to various aspects of the present disclosure. FIGS. 7A-7G are top views of through vias, in portion or entirety, that may be implemented in stacked chip structure 100, according to various aspects of the present disclosure. FIGS. 8A-8G are top views of guard rings that may be formed around a through via, in portion or entirety, and that may be implemented in stacked chip structure 100, according to various aspects of the present disclosure. FIG. 9A is an enlarged, cross-sectional view of the portion of stacked chip structure 100 of FIG. 3 having a different contact configuration, according to various aspects of the present disclosure, and FIG. 9B is a top view of the portion of stacked chip structure 100 of FIG. 9A along line B-B thereof, according to various aspects of the present disclosure. FIG. 10 is a top view of the portion of stacked chip structure 100 of FIG. 9A along line B-B thereof of yet another contact configuration, according to various aspects of the present disclosure. FIGS. 11-15 are enlarged, cross-sectional views of the portion of stacked chip structure 100 of FIG. 3 having different guard ring configurations, according to various aspects of the present disclosure. FIG. 1A, FIG. 1B, FIGS. 2-6, FIGS. 7A-7G, FIGS. 8A-8G, FIG. 9A, FIG. 9B, and FIGS. 10-15 are discussed concurrently herein for ease of description and understanding. FIG. 1A, FIG. 1B, FIGS. 2-6, FIGS. 7A-7G, FIGS. 8A-8G, FIG. 9A, FIG. 9B, and FIGS. 10-15 have been simplified for the sake of clarity to better understand the inventive concepts of the present disclosure. Additional features may be added in stacked chip structure 100, and some of the features described below can be replaced, modified, or eliminated in other embodiments of stacked chip structure 100.

Referring to FIG. 1A, stacked chip structure 100 includes a chip 102 attached to a chip 104 to form an IC (and/or semiconductor) package or portion thereof. Chip 102 and chip 104 each include at least one functional IC, such as an IC configured to perform a logic function, a memory function, a digital function, an analog function, a mixed signal function, a radio frequency (RF) function, an input/output (I/O) function, a communications function, a power management function, other function, or combinations thereof. In some embodiments, chip 102 and chip 104 provide the same function (e.g., both may be central processing units (CPUs)). In some embodiments, chip 102 and chip 104 provide different functions (e.g., one may be a CPU, while the other one may be a graphics processing unit (GPU) or a static random-access memory (SRAM)). In some embodiments, chip 102 and/or chip 104 is a system-on-chip (SoC), which generally refers to a single chip and/or monolithic die having multiple functions. In some embodiments, the SoC is a single chip having an entire system, such as a computer system, fabricated thereon. In some embodiments, the IC package (e.g., stacked chip structure 100) is a system on integrated chip (SoIC) package. The SoIC may have a multichip, hybrid node design, and chip 102 and chip 104 may have different functions (e.g., CPU, GPU, RF, SRAM, etc.) and be fabricated according to different process nodes (e.g., 3 nm (N3), N5, N65, 0.13-micron (μm) (C013), etc.), where the functions and the process nodes may be selected based on design specifications, such as power, performance, area, and cost (PPAC) specifications.

Chip 102 and chip 104 may each include a device layer, such as a device layer DL1 and a device layer DL2, respectively. Device layer DL1 includes a substrate 106 having circuitry fabricated on and/or over a frontside thereof by front end-of-line (FEOL) processing, and device layer DL2 includes a substrate 108 having circuitry fabricated on and/or over a frontside thereof by FEOL processing. For example, device layer DL1 and/or device layer DL2 include various device components/features, such as a semiconductor substrate, doped wells (e.g., n-wells and/or p-wells), isolation features (e.g., shallow trench isolation (STI) structures and/or other suitable isolation structures), gates (e.g., a gate stack having a gate electrode and a gate dielectric), gate spacers along sidewalls of the gates, source/drains (e.g., epitaxial source/drains), other suitable device components and/or device features, or combinations thereof. In some embodiments, device layer DL1 and/or device layer DL2 includes planar transistors, where a channel of a planar transistor is formed in a semiconductor substrate (e.g., substrate 106 and/or substrate 108) between respective source/drains and a respective gate is disposed on the channel (e.g., on a portion of the semiconductor substrate in which the channel is formed). In some embodiments, device layer DL1 and/or device layer DL2 includes non-planar transistors having channels formed in a respective semiconductor fin(s) that extend from a semiconductor substrate and between respective source/drains on/in the semiconductor fin(s), where a respective gate is disposed on and wraps a channel of the semiconductor fin(s) (i.e., the non-planar transistors are fin-like field effect transistors (FinFETs)). In some embodiments, device layer DL1 and/or device layer DL2 includes non-planar transistors having channels formed in semiconductor layers suspended over a substrate and extending between respective source/drains, where a respective gate is disposed on and at least partially surrounds respective channels (i.e., the non-planar transistors are gate-all-around (GAA) transistors and/or fork-sheet transistors). The transistors of device layer DL1 and/or device layer DL2 may be configured as planar transistors and/or non-planar transistors depending on design requirements. In some embodiments, device layer DL1 and/or device layer DL2 include stacked transistors, such as complementary field effect transistors (CFETs) and/or other stacked transistors.

Device layer DL1 and/or device layer DL2 may include various passive microelectronic devices and/or active microelectronic devices, such as resistors, capacitors, inductors, diodes, p-type FETs (PFETs), n-type FETs (NFETs), metal-oxide semiconductor (MOS) FETs (MOSFETs), complementary MOS (CMOS) transistors, bipolar junction transistors (BJTs), laterally diffused MOS (LDMOS) transistors, high voltage transistors, high frequency transistors, other suitable devices and/or components, or combinations thereof. The various microelectronic devices may be configured to provide functionally distinct regions of an IC, such as a logic region (i.e., a core region), a memory region, an analog region, a peripheral region (e.g., an I/O region), a dummy region, other suitable region, or combinations thereof. The logic region may be configured with standard cells, each of which may provide a logic device and/or a logic function, such as an inverter, an AND gate, a NAND gate, an OR gate, a NOR gate, a NOT gate, an XOR gate, an XNOR gate, other suitable logic device, or combinations thereof. The memory region may be configured with memory cells, each of which may provide a storage device and/or storage function, such as flash memory, non-volatile random-access memory (NVRAM), SRAM, dynamic random-access memory (DRAM), other volatile memory, other non-volatile memory, other suitable memory, or combinations thereof. In some embodiments, memory cells and/or logic cells include transistors and interconnect structures that combine to provide storage devices/functions and logic devices/functions, respectively.

Referring to FIG. 2, an enlarged view of a Region I of stacked chip structure 100 of FIG. 1A is provided that depicts a portion of device features and/or device components of a device layer of a chip, such as device layer DL1 of chip 102. In FIG. 2, device layer DL1 includes various transistors, such as a transistor T1 and a transistor T2, formed over/on substrate 106. Device layer DL2 may be configured similar to device layer DL1, and device layer DL2 may include various transistors formed over/on substrate 108 thereof. Transistor T1 and transistor T2 each include a respective gate structure 110 disposed between respective source/drains 112 (e.g., epitaxial source/drains), which are disposed in substrate 106, and transistor T1 and transistor T2 each have a respective channel that extends between respective source/drains 112. Gate structures 110 may include a gate stack (e.g., a gate electrode disposed over a gate dielectric) and gate spacers disposed along sidewalls of the gate stack, and substrate 106 may be a semiconductor substrate (e.g., a silicon substrate). Device layer DL1 may further include isolation structures 114, such as STI structures, that separate and/or electrically isolate transistor T1 and/or transistor T2 from other transistors or devices of device layer DL1.

Device layer DL1 may further include an insulator layer, such as a dielectric layer 116 and a dielectric layer 118, which may be similar to and fabricated similar to dielectric layers described herein. For example, dielectric layer 116 and dielectric layer 118 may have multilayer structures. In some embodiments, dielectric layer 116 and dielectric layer 118 each include a respective interlayer dielectric (ILD) layer and/or a respective contact etch stop layer (CESL). Gate contacts 122 are disposed in dielectric layer 118 and dielectric layer 116, source/drain contacts 124 are disposed in dielectric layer 116, and source/drain vias 126 are disposed in dielectric layer 118. In some embodiments, dielectric layer 116, dielectric layer 118, gate contacts 122, source/drain contacts 124, and source/drain vias 126 form a middle end-of-line (MEOL) layer 130 and/or portion thereof. Additional features can be added in device layer DL1 and/or device layer DL2, and some of the features described can be replaced, modified, or eliminated in other embodiments of device layer DL1 and/or device layer DL2.

Referring back to FIG. 1A, chip 102 and chip 104 may each include a frontside multilayer interconnect (FMLI) structure, such as an FMLI-1 structure over a frontside of substrate 106 and an FMLI-2 structure over a frontside of substrate 108, respectively. Chip 102 and/or chip 104 may further each include a backside multilayer interconnect (BMLI) structure, such as a BMLI-1 structure over a backside of substrate 106 and a BMLI-2 structure over a backside of substrate 108. Each of FMLI-1 structure, FMLI-2 structure, BMLI-1 structure, and BMLI-2 structure includes a combination of dielectric layers (depicted as an insulation layer 140-1, an insulation layer 140-2, an insulation layer 140-1′, and an insulation layer 140-2′, respectively) and electrically conductive layers (e.g., patterned metal layers, each of which may be a group of metal lines, metal vias, metal contacts, or combinations thereof arranged in a desired pattern) that combine to form interconnect (routing) structures (i.e., electrical connections). The interconnect structures may include vertically oriented conductive features, such as metal contacts and/or metal vias, that connect horizontally oriented conductive features, such as metal lines, in different layers/levels (or different planes) of a respective MLI structure. In some embodiments, the interconnect structures route electrical signals between devices and/or components of device layer DL1, device layer DL2, FMLI-1 structure, FMLI-2 structure, BMLI-1 structure, BMLI-2 structure, external devices and/or components, or combinations thereof. In some embodiments, the interconnect structures distribute electrical signals (e.g., clock signals, voltage signals, ground signals, etc.) to the devices and/or the device components of device layer DL1, device layer DL2, FMLI-1 structure, FMLI-2 structure, BMLI-1 structure, BMLI-2 structure, external devices and/or components, or combinations thereof.

FMLI-1 structure includes a device-level contact layer and/or via layer (collectively referred to as a via zero layer (V0 level)), a metal zero layer (M0 level), a via one layer (V1 level), a metal one layer (M1 level), a via two layer (V2 level), a metal two layer (M2 level), and so on to a via (X−1) layer (V(X−1) level), a metal (X−1) layer (M(X−1) level), a via X layer (VX level), and a metal X layer (MX level), where X is an integer (e.g., from 2 to 10). Each level of FMLI-1 structure may include conductive features, such as metal lines 142 or metal vias 144, disposed in insulation layer 140-1. Metal lines 142 of M0 level, M1 level, M2 level, . . . M(X−1) level, and MX level may be referred to as M0 lines, M1 lines, M2 lines, . . . M(X−1) lines, and MX lines, respectively. Metal vias 144 of V0 level, V1 level, V2 level, . . . V(X−1) level, and VX level may be referred to as V0 vias, V1 vias, V2 vias, . . . V(X−1) vias, and VX vias, respectively. Metal vias 144 of V0 level (i.e., the device-level contact layer) may include source/drain contacts (e.g., source/drain contacts 124), source/drain vias (e.g., source/drain vias 126), gate vias (e.g., gate vias 122), or combinations thereof. A metal via 144 may electrically connect an underlying metal line 142 (e.g., a respective M1 line) and an overlying metal line 142 (e.g., a respective M2 line), an underlying device-level contact (e.g., a source/drain contact) and an overlying metal line 142 (e.g., a respective M0 line), or an underlying device feature (e.g., a gate and/or a source/drain) and an overlying metal line 142 (e.g., a respective M0 line).

MLI-2 structure may be similar to FMLI-1 structure. For example, FMLI-2 structure includes a respective V0 level, a respective M0 level, a respective V1 level, a respective M1 level, a respective V2 level, a respective M2 level, and so on to a via (Y−1) layer (V(Y−1) level), a metal (Y−1) layer (M(Y−1) level), a via Y layer (VY level), and a metal Y layer (MY level), where Y is an integer (e.g., from 2 to 10). Y may be less than X, greater than X, or the same as X. Each level of FMLI-2 structure may include conductive features, such as metal lines 146 or metal vias 148, disposed in insulation layer 140-2. Metal lines 146 of M0 level, M1 level, M2 level, . . . M(Y−1) level, and MY level may be referred to as M0 lines, M1 lines, M2 lines, . . . M(Y−1) lines, and MY lines, respectively. Metal vias 148 of V0 level, V1 level, V2 level, . . . V(Y−1) level, and VY level may be referred to as V0 vias, V1 vias, V2 vias, . . . V(Y−1) vias, and VY vias, respectively. A metal via 148 may electrically connect an underlying metal line 146 (e.g., a respective M1 line) and an overlying metal line 146 (e.g., a respective M2 line), an underlying device-level contact (e.g., a source/drain contact) and an overlying metal line 146 (e.g., a respective M0 line), or an underlying device feature (e.g., a gate and/or a source/drain) and an overlying metal line 146 (e.g., a respective M0 line).

Gate contacts 122 may electrically connect gate structures 110 (e.g., gate stacks thereof) to FMLI-1 structure, and source/drain contacts 124 and/or source/drain vias 126 may electrically connect source/drains 112 to FMLI-1 structure. Gate contacts of device layer DL2 may electrically connect gate structures (e.g., gate stacks thereof) of device layer DL2 to FMLI-2 structure, and source/drain contacts and/or source/drain vias of device layer DL2 may electrically connect source/drains thereof to FMLI-2 structure. In some embodiments, gate contacts 122, source/drain contacts 124, and/or source/drain vias 126 are electrically connected to and/or form a portion of FMLI-1 structure. For example, gate contacts 122 and/or source/drain vias 126 may form a portion of V0 level, and gate contacts 122 and/or source/drain vias 126 are electrically connected to metal lines 142 of M1 level. In some embodiments, dielectric layer 116 and dielectric layer 118 form a portion of insulation layer 140-1. In some embodiments, contacts may be disposed in dielectric layer 116 over a doped region in a portion of substrate 106 between transistor T1 and transistor T2, and vias may be disposed in dielectric layer 118 over the contacts. Such contacts may be electrically connected to the doped region, and such vias may be electrically connected to and/or form a portion of FMLI-1 structure.

BMLI-1 structure may be similar to FMLI-1 structure. For example, BMLI-1 structure may include a device-level contact layer and/or a device-level via layer (collectively referred to as a via zero layer (BV0 level)), a metal zero layer (BM0 level), and so on to a via BX′ layer (BVX′ level) and a metal BX′ layer (BMX′ level), where X′ is an integer (e.g., from 1 to 10). X′ may be less than, greater than, or the same as X. In some embodiments, X′ equals 2, and BMLI-1 structure may include a BV0 level, a BV1 level, a BM1 level, a BV2 level, and a BM2 level. Each level of BMLI-1 structure may include conductive features, such as metal lines 142′ or metal vias 144′, disposed in insulation layer 140-1′ and/or substrate 106. Metal lines 142′ of BM1 level and BM2 level may be referred to as BM1 lines and BM2 lines, respectively. Metal vias 144′ of BV0 level, BV1 level, and BV2 level may be referred to as BV0 vias, BV1 vias, and BV2 vias. A BV0 via (e.g., a metal via 144′) of BV0 level may be disposed in substrate 106, in some embodiments, and a metal via 144′ of BV0 level may electrically connect a metal via of FMLI-1 structure (e.g., a metal via 144 of V0 level thereof) to a metal via of BMLI-1 structure (e.g., a metal via 144′ of BV1 level thereof). In some embodiments, a metal via 144′ may electrically connect an underlying metal line 142′ (e.g., a respective BM1 line) and an overlying metal line 142′ (e.g., a respective BM2 line). In some embodiments, one or more metal lines 142′ of BMLI-1 structure may be power rails, which may be electrically connected to transistors of device layer DL1, for example, by a collection of metal vias 144′ and/or metal lines 142′. BMLI-1 structure may have more or less layers/levels than depicted.

BMLI-2 structure may be similar to BMLI-1 structure. For example, BMLI-2 structure may include a respective BV0 level, a respective BM0 level, a respective BV1 level, a respective BM1 level, a respective BV2 level, a respective BM2 level, and so on to a via (BY′−1) layer (V(BY′−1) level), a metal (BY′−1) layer (M (BY′−1) level), a via BVY′ layer (BVY′ level), and a metal BY′ layer (BMY′ level), where Y is an integer (e.g., from 1 to 10). Y′ may be less than, greater than, or the same as Y. Each level of BMLI-2 structure may include conductive features, such as metal lines 146′ or metal vias 148′, disposed in insulation layer 140-2′ and/or substrate 108. A metal via 148′ may electrically connect an underlying metal line 146′ (e.g., a respective BM0 line) and an overlying metal line 146′ (e.g., a respective BM1 line), an underlying device-level contact (e.g., a source/drain contact) and an overlying metal line 146′ (e.g., a respective M0 line), or an underlying device feature (e.g., a gate and/or a source/drain) and an overlying metal line 146′ (e.g., a respective M0 line). In some embodiments, one or more metal lines 146′ of BMLI-2 structure may be power rails, which may be electrically connected to transistors of device layer DL2, for example, by a collection of metal vias 148′ and/or metal lines 146′. BMLI-2 structure may have more or less layers/levels than depicted.

Device level (e.g., a bottommost level) of FMLI-1 structure (e.g. V0 level), FMLI-2 structure (e.g., V0 level), BMLI-1 structure (e.g., BV0 level), and BMLI-2 structure (e.g., BV0 level) may be fabricated by middle-of-line (MOL) processing, and additional levels of FMLI-1 structure (e.g. M0 level and up), FMLI-2 structure (e.g., M0 level and up), BMLI-1 structure (e.g., BM0 level and up), and BMLI-2 structure (e.g., BM0 level and up) may be fabricated by back-end-of-line (BEOL) processing. V0 levels of chip 102 and chip 104 may thus be referred to as an MOL structures, and M0 level and up of chip 102 and chip 104 may be referred to as BEOL structures. In some embodiments, V0 level and/or BV0 level may include an MD level formed by source/drain contacts and a VD/VG level formed by source/drain vias and/or gate contacts. Further, on a backside of device layer DL1, BV0 level may include backside source/drain contacts and/or backside vias, both of which may extend into and/or through substrate 106. The backside source/drain contacts and/or backside vias may be disposed in electrically insulated portions of substrate 106, such as in one or more backside dielectric layer(s) and/or isolation structures thereof. Backside source/drain contacts may electrically connect a backside of a respective source/drain to a respective metal line 142′ of BM0 level of BMLI-1 structure. Backside vias may electrically connect a respective metal line 142′ of BM0 level of BMLI-1 structure to a respective metal via 144 of V0 level of FMLI-1 structure.

Insulation layer 140-1, insulation layer 140-1′, insulation layer 140-2, and insulation layer 140-2′ include an electrically insulating material. For example, insulation layer 140-1, insulation layer 140-1′, insulation layer 140-2, and insulation layer 140-2′ include one or more dielectric material(s), such as silicon oxide, tetraethylorthosilicate (TEOS) oxide, phosphosilicate glass (PSG), boron-doped silicate glass (BSG), boron-doped PSG (BPSG), low-k dielectric material (e.g., having a dielectric constant less than a dielectric constant of silicon oxide (e.g., k<3.9)), other suitable dielectric material, or combinations thereof. Example low-k dielectric materials include fluorosilicate glass (FSG), carbon-doped oxide, xerogel, aerogel, amorphous fluorinated carbon, parylene, polyimide, other low-k dielectric material, or combinations thereof. In some embodiments, insulation layer 140-1, insulation layer 140-1′, insulation layer 140-2, insulation layer 140-2′, or combinations thereof include carbon-doped oxide and/or porous carbon-doped oxide (e.g., extreme low-k dielectric material (e.g., k≤2.5)).

In some embodiments, insulation layer 140-1, insulation layer 140-1′, insulation layer 140-2, insulation layer 140-2′, or combinations thereof have a multilayer structure. For example, insulation layer 140-1, insulation layer 140-1′, insulation layer 140-2, insulation layer 140-2′, or combinations thereof may each include at least one ILD layer, at least one CESL disposed between respective ILD layers, and at least one CESL disposed between a respective ILD layer and device substrates (e.g., substrate 106 and/or substrate 108). For example, referring to FIG. 3, insulation layer 140-1 may include ILD layers 150 and CESLs 152, and insulation layer 140-1′ may include ILD layers 150 and CESLs 152′. Compositions of CESLs 152 are different than compositions of ILD layers 150, and compositions of CESLs 152′ are different than compositions of ILD layers 150′. For example, ILD layers 150 and ILD layers 150′ may include a low-k dielectric material that includes silicon and oxygen, and CESLs 152 and CESLs 152′ may include silicon and nitrogen (e.g., silicon nitride, silicon oxynitride, silicon carbonitride, or combinations thereof) or other suitable dielectric material (e.g., metal nitride). ILD layers 150, ILD layers 150′, CESLs 152, CESLs 152′, or combinations thereof may have a multilayer structure and/or include multiple dielectric materials. In some embodiments, dielectric layer 116 and/or dielectric layer 118 form a portion of insulation layer 140-1.

In some embodiments, each level of FMLI-1 structure (e.g., 2nd level including M2 level and V2 level) may include a respective ILD layer 150 and/or a respective CESL 152 of insulation layer 140-1, and respective metal lines 142 and metal vias 144 may be disposed therein. In some embodiments, each level of BMLI-1 structure (e.g., 2nd level including BM2 level and BV2 level) may include a respective ILD layer 150′ and/or a respective CESL 152′ of insulation layer 140-1′, and respective metal lines 142′ and metal vias 144′ may be disposed therein. In some embodiments, each level of FMLI-2 structure may include a respective ILD layer and/or a respective CESL of insulation layer 140-2, and respective metal lines 146 and metal vias 148 may be disposed therein. In some embodiments, each level of BMLI-2 structure may include a respective ILD layer and/or a respective CESL of insulation layer 140-2′, and respective metal lines 146′ and metal vias 148′ may be disposed therein. In some embodiments, each of M0 level to MX level of FMLI-1 structure and/or each of BM0 level to BMX′ level of BMLI-1 structure may include a respective ILD layer and/or a respective CESL, and respective metal lines 142 and/or respective metal lines 142′ may be disposed therein. In some embodiments, each of M0 level to MY level of FMLI-2 structure and/or each of BM0 to BMY′ of BMLI-2 structure may include a respective ILD layer and/or a respective CESL, and respective metal lines 146 and/or respective metal lines 146′ may be disposed therein. In some embodiments, each of V0 level to VX level of FMLI-1 structure and/or each of BV0 level to BVX′ level of BMLI-1 structure may include a respective ILD layer and/or a respective CESL, and respective metal vias 144 and/or respective metal vias 144′ may be disposed therein. In some embodiments, each of V0 level to VY level of FMLI-2 structure and/or each of BV0 to BVY′ of BMLI-2 structure may include a respective ILD layer and/or a respective CESL, and respective metal vias 148 and/or respective metal vias 148′ may be disposed therein.

Metal lines 142, metal vias 144, metal lines 142′, metal vias 144′, metal lines 146, metal vias 148, metal lines 146′, metal vias 148′, source/drain contacts (e.g., source/drain contact 124), source/drain vias (e.g., source/drain via 126), gate contacts (e.g., gate contacts 122), or combinations thereof include an electrically conductive material, which may include aluminum, copper, titanium, tantalum, tungsten, ruthenium, cobalt, iridium, palladium, platinum, nickel, tin, gold, silver, other suitable metals, alloys thereof, silicides thereof, or combinations thereof. In some embodiments, metal lines 142, metal vias 144, metal lines 142′, metal vias 144′, metal lines 146, metal vias 148, metal lines 146′, metal vias 148′, source/drain contacts, source/drain vias, gate contacts, or combinations thereof include a bulk metal layer (also referred to as a metal fill layer, a conductive plug, a metal plug, etc.). In some embodiments, metal lines 142, metal vias 144, metal lines 142′, metal vias 144′, metal lines 146, metal vias 148, metal lines 146′, metal vias 148′, source/drain contacts, source/drain vias, gate contacts, or combinations thereof include a barrier layer, an adhesion layer, other suitable layer, or combinations thereof disposed between the bulk metal layer and a respective insulation layer. The barrier layer may include titanium, titanium alloy (e.g., TiN), tantalum, tantalum alloy (e.g., TaN), other suitable barrier material (e.g., a material that may prevent diffusion of metal constituents from the bulk metal layer into a surrounding dielectric), or combinations thereof. In some embodiments, metal lines 142, metal vias 144, metal lines 142′, metal vias 144′, metal lines 146, metal vias 148, metal lines 146′, metal vias 148′, source/drain contacts, source/drain vias, gate contacts, or combinations thereof include different metal materials. For example, lower metal lines 142, metal vias 144, metal lines 142′, metal vias 144′, or combinations thereof, which are closer to device layer DL1, may include tungsten, ruthenium, cobalt, or combinations thereof, while higher metal lines 142, metal vias 144, metal lines 142′, metal vias 144′, which are further away from device layer DL1, may include copper. In another example, lower metal lines 146, metal vias 148, metal lines 146′, metal vias 148′, or combinations thereof, which are closer to device layer DL2, may include tungsten, ruthenium, cobalt, or combinations thereof, while higher metal lines 146, metal vias 148, metal lines 146′, metal vias 148′, or combinations thereof, which are further away from device layer DL2, may include copper. In some embodiments, metal lines 142, metal vias 144, metal lines 142′, metal vias 144′, metal lines 146, metal vias 148, metal lines 146′, metal vias 148′, source/drain contacts, source/drain vias, gate contacts, or combinations thereof include the same metal materials.

A carrier substrate (wafer) 158 may be attached (bonded) to frontside of chip 104. In the depicted embodiment, FMLI-2 structure is attached to carrier substrate 158, for example, by a bonding/adhesion structure. The bonding/adhesion structure may include any suitable material (e.g., oxide) that facilitates bonding/adhesion of carrier substrate 158 with insulation layer 140-2 and/or metal lines 146 of FMLI-2 structure. In some embodiments, carrier substrate 158 includes bulk silicon (e.g., carrier substrate 158 may be a silicon substrate). In some embodiments, carrier substrate 158 includes another suitable material that provides sufficient rigidity and/or mechanical support for chip 104 and/or stacked chip structure 100.

Chip 102 and chip 104 are stacked and attached (bonded) front-to-back and/or face-to-back, in the depicted embodiment. For example, chip 102 has a frontside FS1 formed by FMLI-1 structure and a backside BS1 formed by BMLI-1 structure, chip 104 has a frontside FS2 formed by FMLI-2 structure and a backside BS2 formed by BMLI-2 structure, and FMLI-1 structure is attached (bonded) to BLMI-2 structure. Face-to-back bonding of chip 102 and chip 104 may be achieved by dielectric-to-dielectric bonding (e.g., oxide-to-oxide bonding), metal-to-metal bonding (e.g., copper-to-copper bonding), metal-to-dielectric bonding (e.g., copper-to-oxide bonding), other type of bonding, or combinations thereof. In some embodiments, chip 102 is mounted on chip 104 using hybrid bonding (i.e., using both metal-to-metal bonding and nonmetal-to-nonmetal bonding), and chip 104 may be electrically connected to chip 102 via the hybrid bonding, such as via bonding/interconnect structure 160. For example, chip 102 and chip 104 may each include a non-metal portion (e.g., a bonding layer 162-1 and a bonding layer 162-2, respectively) and a metal portion (e.g., bonding pads 164-1 and bonding pads 164-2, respectively (also referred to as bonding pad metal (BPM))). The non-metal portions of chip 102 may be bonded to the non-metal portions of chip 104, and the metal portions of chip 102 may be bonded to the metal portions of chip 104. In some embodiments, bonding pads 164-1 are disposed in bonding layer 162-1, bonding pads 164-2 are disposed in bonding layer 162-2, bonding pads 164-1 may be bonded to bonding pads 164-2, and bonding layer 162-1 may be bonded to bonding layer 162-2. In some embodiments, such as depicted, bonding pads 164-1 may partially overlap bonding pads 164-2 and partially overlap bonding layer 162-2, and bonding pads 164-2 may partially overlap bonding pads 164-1 and partially overlap bonding layer 162-1. In some embodiments, chip 102 may include a bonding layer 166-1 and bonding vias 168-1 (also referred to as bonding pad vias (BPVs)) disposed therein, and chip 104 may further include a bonding layer 166-2 and bonding vias 168-2 disposed therein. Bonding vias 168-1 may be connected to bonding pads 164-1, and bonding vias 168-2 may be connected to bonding pads 164-2. In some embodiments, bonding layer 162-1, bonding layer 162-2, bonding layer 166-1, bonding layer 166-2, or combinations thereof are polymer layers, which may include benzocyclobutene (BCB), polyimide (PI), polybenzoxazole (PBO), other polymer material, or combinations thereof. In some embodiments, bonding layer 162-1, bonding layer 162-2, bonding layer 166-1, bonding layer 166-2, or combinations thereof are dielectric layers. In some embodiments, bonding pads 164-1, bonding pads 164-2, bonding vias 168-1, bonding vias 168-2, or combinations thereof include copper, aluminum, other suitable metal, alloys thereof, or combinations thereof. In some embodiments, bonding layer 162-1, bonding layer 162-2, bonding layer 166-1, bonding layer 166-2, bonding pads 164-1, bonding pads 164-2, bonding vias 168-1, bonding vias 168-2, or combinations thereof have multilayer structures.

Chip 102 and/or chip 104 may include additional structures that facilitate connection thereto. For example, in the depicted embodiment, chip 102 further includes a top contact structure (and/or layer), such as a TC-1 structure, and a bottom contact structure (and/or layer), such as BC-1 structure. TC-1 structure may be disposed over a front side of device layer DL1, such as over FMLI-1 structure, and BC-1 structure may be disposed over a backside of device layer DL1, such as over BMLI-1 structure. In some embodiments, TC-1 structure is disposed over a topmost level/layer of FMLI-1 structure (i.e., MX level thereof), and BC-1 structure is disposed over a bottommost level/layer of BMLI-1 structure (i.e., BMX′ level thereof). TC-1 structure includes an insulation layer 170-1 and electrically conductive features, such as metal lines 172 and metal vias 174, arranged in a desired pattern therein. BC-1 structure includes an insulation layer 170-1′ and electrically conductive features, such as metal lines 172′ and metal vias, arranged in a desired pattern therein. In some embodiments, insulation layer 170-1 is a passivation layer, which may be formed of a material that is different than a material of insulation layer 140-1 (e.g., of an ILD layer thereof). In some embodiments, insulation layer 170-1′ is a passivation layer, which may be formed of a material that is different than a material of insulation layer 140-1′ (e.g., of an ILD layer thereof). In some embodiments, a dielectric constant of insulation layer 170-1 is greater than a dielectric constant of a topmost dielectric layer (e.g., an ILD layer) of FMLI-1 structure, over which insulation layer 170-1 may be formed and/or disposed on. In some embodiments, a dielectric constant of insulation layer 170-1′ is greater than a dielectric constant of a topmost dielectric layer (e.g., an ILD layer) of BMLI-1 structure, over which insulation layer 170-1′ may be formed and/or disposed on.

Insulation layer 170-1 and insulation layer 170-1′ include an electrically insulating material, such as polyimide, undoped silicate glass (USG), BCB, polybenzoxazole, silicon oxynitride, silicon nitride, silicon oxide, epoxy, other suitable insulating material, or combinations thereof. For example, insulation layer 170-1 and/or insulation layer 170-1′ may be polyimide layers. In some embodiments, insulation layer 170-1 and/or insulation layer 170-1′ has a multilayer structure and may include multiple electrically insulating materials. For example, referring to FIG. 3, insulation layer 170-1 may include an insulation layer 170-1a, an insulation layer 170-1b, and an insulation layer 170-1c, and insulation layer 170-1′ may include an insulation layer 170-1′a, an insulation layer 170-1′b, and an insulation layer 170-1′c. Insulation layer 170-1a, insulation layer 170-1b, and insulation layer 170-1c may have the same or different compositions. In some embodiments, insulation layer 170-1c is a USG layer, insulation layer 170-1b is a silicon nitride layer, and insulation layer 170-1a is a dielectric layer having a different composition than insulation layer 170-1b and insulation layer 170-1c, such as a hydrogen-and-nitrogen doped carbide layer. Insulation layer 170-1′a, insulation layer 170-1′b, and insulation layer 170-1′c may have the same or different compositions. In some embodiments, insulation layer 170-1c is a USG layer, insulation layer 170-1b is a silicon nitride layer, and insulation layer 170-1a is a USG layer. In some embodiments, insulation layer 170-1a, insulation layer 170-1b, insulation layer 170-1c, insulation layer 170-1′a, insulation layer 170-1′b, insulation layer 170-1′c, or combinations thereof are ESLs.

In some embodiments, chip 102 may include a redistribution layer (RDL) structure, such as RDL-1 structure, and/or chip 104 may include an RDL structure, such as RDL-2 structure. RDL-1 structure and RDL-2 structure electrically connect chip 102 and/or chip 104 (e.g., components and/or devices thereof, such as transistors) to external circuitry and/or external devices. For example, RDL-2 structure may electrically connect chip 104 to chip 102 (e.g., BMLI-2 structure to FMLI-1 structure), and RDL-1 structure may electrically connect chip 102 and/or stacked chip structure 100 to external circuitry/devices. In some embodiments, RDL-1 structure and/or RDL-2 structure redistributes a layout of connections between devices and/or components of chip 102 and/or chip 104 to facilitate signal transmission and/or power transmission. In some embodiments, RDL-1 structure and/or RDL-2 structure redistributes bonding pads to different locations, such as from peripheral locations to being uniformly distributed over a surface of stacked chip structure 100 (and/or chip 102 thereof).

RDL-1 structure includes an insulation layer 180-1 and electrically conductive features, such as metal lines 182 and metal vias 184, arranged in a desired pattern therein. RDL-2 structure includes an insulation layer 180-2 and electrically conductive features, such as metal lines 186 and metal vias 188, arranged in a desired pattern therein. Insulation layer 180-1 and insulation layer 180-2 include an electrically insulating material, such as polyimide, USG, BCB, polybenzoxazole, silicon oxynitride, silicon nitride, silicon oxide, epoxy, other suitable insulating material, or combinations thereof. In some embodiments, insulation layer 180-1 and/or insulation layer 180-2 has a multilayer structure and may include multiple electrically insulating materials. Metal lines 172, metal vias 174, metal lines 172′, metal lines 182, metal vias 184, metal lines 186, metal vias 188, or combinations thereof include an electrically conductive material, which may include aluminum, copper, titanium, tantalum, tungsten, ruthenium, cobalt, iridium, palladium, platinum, nickel, tin, gold, silver, other suitable metals, alloys thereof, silicides thereof, or combinations thereof. In some embodiments, metal lines 172, metal vias 174, metal lines 172′, metal lines 182, metal vias 184, metal lines 186, metal vias 188, or combinations thereof include a bulk metal layer. In some embodiments, metal lines 172, metal vias 174, metal lines 172′, metal lines 182, metal vias 184, metal lines 186, metal vias 188, or combinations thereof include a barrier layer, an adhesion layer, other suitable layer, or combinations thereof disposed between the bulk metal layer and a respective insulation layer. The barrier layer may include titanium, titanium alloy (e.g., TiN), tantalum, tantalum alloy (e.g., TaN), other suitable barrier material (e.g., a material that may prevent diffusion of metal constituents from the bulk metal layer into a surrounding dielectric), or combinations thereof. Metal lines 172, metal vias 174, metal lines 172′, metal lines 182, metal vias 184, metal lines 186, and metal vias 188 may include the same or different metal materials.

In some embodiments, stacked chip structure 100 includes a bump structure. For example, a bump structure may be formed over chip 102 (e.g., backside BS1 thereof), and the bump structure may electrically connect chip 102 and/or chip 104 to a power supply. The bump structure may include an insulation layer 192 and connectors 194 disposed therein. In the depicted embodiment, insulation layer 192 and connectors 194 are disposed on RDL-1 structure, and connectors 194 are electrically connected to RDL-1 structure (e.g., metal lines 182 thereof). Insulation layer 192 may include an electrically insulating material(s), such as those described herein. In some embodiments, insulation layer 192 is a passivation layer. Connectors 194 may include a respective under-bump metallization (UBM) pillar structure and a respective solder bump/cap. For example, connectors 194 may include UBM pillar structures 195 and bumps 196. UBM pillar structures 195 and bumps 196 may include electrically conductive materials, such as those described herein. In some embodiments, connectors 194 may be formed as controlled-collapse chip connection bumps (C4 bumps), ball grid array (BGA) bumps, land grid array (LGA) bumps, pin grid array (PGA) bumps, microbumps, or the like.

Stacked chip structure 100 may further include an encapsulant 198 (also referred to as a molding, a molding compound, and/or a silicon oxide-based compound). Chip 102, chip 104, and corresponding bonding and/or interconnect structures (e.g., bonding/interconnection structure 160, TC-1 structure, BC-1 structure, RDL-1 structure, RDL-2 structure, the bump structure thereon, etc.) may be disposed in and/or covered by encapsulant 198. For example, encapsulant 198 may circumferentially surround chip 102 and/or chip 104. In some embodiments, encapsulant 198 is disposed on edges/sidewalls of chip 102 and/or edges/sidewalls of chip 104. In some embodiments, encapsulant 198 includes an organic material, such as an epoxy-based material, and/or a gap fill material (e.g., an organic material), such as an oxide-based material.

Referring to FIG. 1A, FIG. 3, and FIG. 4, chip 102 further includes one or more through substrate vias (TSVs) 200 (also referred to as a through silicon via or a through semiconductor via). In the depicted embodiment, TSVs 200 extend from a respective metal line 172′ of BC-1 structure, through insulation layer 170-1′, through insulation layer 140-1′, through device layer DL1 (including substrate 106 thereof), and through insulation layer 140-1 to a respective metal line 142 of FMLI-1 structure (e.g., of MX level thereof). TSVs 200 have a dimension D, such as a width or a diameter, along the x-direction and/or the y-direction, and a height H1 along the z-direction. In some embodiments, dimension D is substantially the same along height H1. In some embodiments, dimension D varies along height H1. For example, TSVs 200 may have tapered sidewalls as depicted, such that dimension D decreases from a top of TSV 200 (abutting a respective one of metal lines 172′) to a bottom of TSV 200 (abutting a respective one of metal lines 142). The present disclosure contemplates TSVs 200 having any variation of dimension D along height H1 depending on sidewall configurations thereof.

TSVs 200 may have a circular shape in a top view, such as depicted in FIG. 4 and FIG. 7A. In such embodiments, TSVs 200 may be cylindrical structures, and dimension D may be a diameter of TSVs 200. In some embodiments, TSVs 200 have different shapes in a top view, such as those depicted in FIGS. 7B-7G. For example, TSVs 200 may be square shaped (FIG. 7B), rectangular shaped (FIG. 7C), rhombus shaped, trapezoidal shaped, polygon shaped, oval shaped (FIG. 7D), diamond shaped (FIG. 7E), hexagonal shaped (FIG. 7F), octagonal shaped (FIG. 7G), other suitably shaped, or combinations thereof.

TSVs 200 include an electrically conductive material, which may include aluminum, copper, titanium, tantalum, tungsten, ruthenium, cobalt, iridium, palladium, platinum, nickel, tin, gold, silver, other suitable metals, alloys thereof, silicides thereof, or combinations thereof. In some embodiments, such as depicted in FIG. 3, TSVs 200 includes a conductive plug 202 (also referred to as a bulk metal layer, a metal fill layer, a metal plug, or the like) and a barrier 204. Barrier 204 is disposed between conductive plug 202 and insulation layer 140-1, insulation layer 140-1′, and substrate 106 (e.g., an insulative portion thereof). Barrier 204 may include titanium, titanium alloy (e.g., TiN), tantalum, tantalum alloy (e.g., TaN), other suitable barrier constituent and/or material (e.g., a material that can prevent and/or reduce diffusion of metal constituents (e.g., copper) from TSVs 200 into insulation layer 140-1, insulation layer 140-1′, and substrate 106), or combinations thereof. In some embodiments, conductive plug 202 is a copper plug or a tungsten plug, and barrier 204 is a metal nitride layer (e.g., TaN layer and/or TiN layer). In some embodiments, conductive plug 202 is a polysilicon plug. In some embodiments, conductive plug 202 and/or barrier 204 has a multilayer structure. For example, conductive plug 202 may include a bulk metal layer and a seed layer, and the seed layer may be disposed between barrier 204 and the bulk metal layer. The seed layer may include copper, tungsten, other suitable metals (such as those described herein), alloys thereof, or combinations thereof.

In some embodiments, referring to FIG. 6, an insulation liner 206 (e.g., a dielectric liner) is between TSVs 200 and insulation layer 140-1, insulation layer 140-1′, and substrate 106 (e.g., an insulative portion thereof). For example, insulation liner 206 may be disposed along sidewalls of TSVs 200 (e.g., those formed by barrier 204 and/or conductive plug 202), but not bottoms of TSVs 200, such that insulation liner 206 is between the sidewalls of TSVs 200 and insulation layer 140-1, insulation layer 140-1′, and substrate 106. Insulation liner 206 includes silicon oxide, silicon nitride, silicon carbide, other suitable dielectric material, or combinations thereof. In some embodiments, insulation liner 206 has a multilayer structure, such as a silicon nitride layer (e.g., an Si₃N₄ layer) and a silicon carbide layer (e.g., an SiC layer). Insulation liner 206 is formed by atomic layer deposition (ALD), chemical vapor deposition (CVD), thermal oxidation (e.g., in a dry oxygen environment), other suitable process, or combinations thereof. Incorporating insulation liner 206 between TSVs 200 and their surrounding material (e.g., insulation layer 140-1, insulation layer 140-1′, and substrate 106) may improve electrical insulation of TSVs 200 from electrically conductive structures/features proximate thereto (e.g., metal lines 142, metal lines 142′, metal vias 144, metal vias 144′ etc.), reduce capacitance, etc.

Referring again to FIG. 3, TSVs 220 abut respective metal lines 142 (e.g., at MX level) to facilitate electrical connection to chip 102 (e.g., transistors thereof at device layer DL1) and/or chip 104 (e.g., transistors thereof at device layer DL2). In some embodiments, instead of stopping at metal line 142 (e.g., at MX level), TSVs 220 may extend into and/or through their respective metal landing pads. For example, an end of TSV 220 may include a contact via 210 that extends into and/or through a respective metal line 142. In the depicted embodiment, contact via 210 (which may be formed from conductive plug 202 and/or barrier 204) extends beyond its respective metal line 142 and into insulation layer 170-1 of TC-1 structure. In some embodiments, such as depicted in FIG. 5, metal landing pads (e.g., metal lines 142 of MX level (i.e., MX lines)) may be patterned to include contact via openings therein, such as a contact via opening 142O, for forming contact via 210. The present disclosure contemplates TSVs 220 having any number of contact vias 210, and thus, MX lines may be patterned with any number of contact via openings 142O. For example, referring to FIG. 9A and FIG. 9B, one or more TSVs 220 may include two contact vias 210, and metal line(s) 142 upon which such TSVs 220 land are patterned to include two contact via openings 142O. In some embodiments, one or more of TSVs 220 may include one to ten contact vias 210, and thus, any metal line 142 upon which such TSVs 220 land are patterned to include one to ten contact via openings 142O. For example, referring to FIG. 10, one or more TSVs 220 may include four contact vias 210, and metal line(s) 142 upon which such TSVs 220 land are patterned to include four contact via openings 142O. Forming contact via openings 142O while fabricating metal lines 142 (i.e., during fabrication of FMLI-1 structure) may reduce and/or prevent stress induced contact via overlay issues. For example, greater metal density often leads to greater local residual stress, which can cause warpage and/or bending of metal lines 142 and/or locally thereto that reduces overlay accuracy. Inserting contact via openings 142O into metal lines 142 may thus improve overlay accuracy by reducing metal density of metal lines 142. Further, implementing more than one contact via 210 may lower overall contact resistance. In some embodiments, a contact resistance associated with each contact via 210 may be about 0.01Ω to about 0.05Ω. In some embodiments, providing TSVs 220 with contact vias 210 (e.g., one to ten) may reduce contact resistance by about 5%. In some embodiments, metal lines 142 are further patterned to include dummy contact via openings 142o, such as depicted in FIG. 10, which may further reduce metal density thereof and improve overlay. Dummy contact via openings 142o may subsequently be filled with insulation material, such as that of insulation layer 140-1 and/or subsequently formed insulation layer 170-1.

Referring to FIG. 1A, FIG. 3, and FIG. 4, chip 102 further includes one or more guard ring structures 220. In the depicted embodiment, guard ring structures 220 extend through insulation layer 140-1′, through device layer DL1 (including substrate 106 thereof), and through insulation layer 140-1, and guard ring structures 220 extend from insulation layer 170-1′ of BC-1 structure to a respective metal line 142 of FMLI-1 structure (e.g., of MX level thereof). Guard ring structures 220 are spaced apart from and around one or more TSVs 200, and insulation layer 140-1, insulation layer 140-1′, and substrate 106 (e.g., an insulative portion thereof) may fill the spacing between guard ring structures 220 and their respective TSV(s) 200. In some embodiments, each TSV 200 has a corresponding, respective guard ring structure 220. For example, referring to FIG. 3 and FIG. 4, a guard ring structure 220 is spaced apart from and around a respective TSV 200, and insulation layer 140-1, insulation layer 140-1′, and substrate 106 (e.g., an insulative portion thereof) may fill spacing between guard ring structure 220 and the respective TSV 200. A height H2 (e.g., along the z-direction) of guard ring structure 220 is less than height H1 of TSV 200. In a top, plan view, guard ring structure 220 may be square shaped and provide a square ring around TSV 200, such as depicted in FIG. 4 and FIG. 8B, such that in the depicted embodiment, guard ring structure 220 has a different shaped top profile than its respective TSV(s) 200. In some embodiments, guard ring structures 220 have different shapes in a top view, such as those depicted in FIG. 8A and FIGS. 8C-8G. For example, guard ring structures 220 may be circular shaped rings (FIG. 8A), rectangular shaped rings (FIG. 8C), rhombus shaped rings, trapezoidal shaped rings, polygon shaped rings, oval shaped rings (FIG. 8D), diamond shaped rings (FIG. 8E), hexagonal shaped rings (FIG. 8F), octagonal shaped rings (FIG. 8G), other suitably shaped rings, or combinations thereof. In some embodiments, from a top view, guard ring structures 220 and their respective TSV(s) 200 have the same shape (e.g., both may have circular shaped profiles when viewed from tops thereof). In the depicted embodiment, from a top view, guard ring structure 220 extends continuously around its respective TSV(s) 200. In some embodiments, guard ring structure 220 is discontinuous around its respective TSV(s) 200. For example, guard ring structure 220 may be formed by discrete segments that combine to form a ring around its respective TSV(s) 200.

In some embodiments, guard ring structure 220 is electrically connected to a voltage. In some embodiments, guard ring structure 220 is electrically connected to an electrical ground. In some embodiments, guard ring structure 220 is configured to spatially and/or electrically insulate/isolate its respective TSV(s) 200 from FMLI-1 structure (e.g., from metal lines 142 and/or metal vias 144 thereof), BMLI-1 structure (e.g., from metal lines 142′ and/or metal vias 144′ thereof), device layer DL1 (e.g., from substrate 106 and/or devices thereof), other features/components, or combinations thereof. In some embodiments, guard ring structure 220 absorbs and/or reduces thermal stress and/or mechanical stress from, within, and/or around TSV 200. Such stresses may result from TSV(s) 200, device layer DL1 (e.g., substrate 106 thereof), FMLI-1 structure (e.g., insulation layer 140-1 thereof), and BMLI-1 structure (e.g., insulation layer 140-1′ thereof) having different coefficients of thermal expansion (CTE). Such stresses may result during and/or after fabrication of TSV(s) 200. In some embodiments, guard ring structure 220 provides structural support, integrity, reinforcement, or combinations thereof for TSV(s) 200. In some embodiments, guard ring structure 220 is electrically connected to substrate 106, such as to a doped region (e.g., an n-well and/or a p-well) therein.

One or more guard ring structures 220, such as guard ring structure 220 depicted in FIG. 3 and FIG. 4, have a dual guard ring (DGR) structure. For example, guard ring structure 220 includes a primary guard ring 220A (also referred to as a primary guard ring segment) and a secondary guard ring 220B (also referred to as a secondary guard ring segment). Primary guard ring 220A is disposed in and extends through insulation layer 140-1′, device layer DL1, and insulation layer 140-1, and secondary guard ring 220B is disposed in and extends through insulation layer 140-1. In some embodiments, from a top view (FIG. 4), primary guard ring 220A and secondary guard ring 220B extend continuously around TSV(s) 200, and primary guard ring 220A and secondary guard ring 220B have the same shape. For example, both are square shaped rings. In some embodiments, primary guard ring 220A and secondary guard ring 220B may have different shaped profiles from a top view (or bottom view).

Primary guard ring 220A and secondary guard ring 220B may be fabricated in conjunction with FMLI-1 structure and BMLI-1 structure, and primary guard ring 220A and secondary guard ring 220B may be considered a portion of and/or formed from a portion of FMLI-1 structure and/or BMLI-1 structure. For example, primary guard ring 220A and secondary guard ring 220B may be formed of metal lines 142 and metal vias 144, which may correspond with the various levels of FMLI-1 structure, and/or metal lines 142′ and metal vias 144′, which may correspond with the various levels of BMLI-1 structure. In the depicted embodiment, primary guard ring segment 220A extends from BM2 level to BV0 level, through device layer DL1, and from V0 level to M0 level, and primary guard ring 220A includes a frontside interconnect structure stack disposed in and extending through insulation layer 140-1, a backside interconnect structure stack disposed in and extending through insulation layer 140-1′, and a device-level interconnect structure disposed in and extending through device layer DL1. In furtherance of the depicted embodiment, secondary guard ring segment 220B extends from M(X−1) level to VX level, and secondary guard ring segment 220B includes a frontside interconnect structure stack disposed in and extending through insulation layer 140-1. Each interconnect structure of frontside interconnect structure stack(s) may include a respective metal line 142 and a respective metal via 144, and each interconnect structure of backside interconnect structure stack(s) may include a respective metal line 142′ and a respective metal via 144′. In some embodiments, an interconnect structure of device-level interconnect structure may be formed of metal vias 144 and/or metal vias 144′ at V0 level and/or BV0 level, respectively, which may be disposed in and/or extend through substrate 106. In some embodiments, an interconnect structure of device-level interconnect structure may include electrically conductive features (e.g., vias) that connect respective metal vias 144 at V0 level and respective metal vias 144′ at BV0 level. The frontside interconnect structure stack and/or the backside interconnect structure stack may have more or less interconnect structures, and the frontside interconnect structure stack and/or the backside interconnect structure stack may have a number of interconnect structures that is more than, less than, or the same as a number of levels of FMLI-1 structure and a number of levels of BMLI-1 structure, respectively.

Primary guard ring 220A overlaps the sidewall of TSV 220 in BMLI-1 structure, FMLI-1 structure, and device layer DL1. Primary guard ring 220A is thus disposed between the sidewall of TSV 200 and metal lines 142′/metal vias 144′ of BMLI-1 structure, metal lines 142/metal vias 144 of FMLI-1 structure, and devices of device layer DL1. Primary guard ring 220A has a height h1 (e.g., along the z-direction), and height h1 is less than height H2. Since primary guard ring 220A is configured to provide a majority of the spatial isolation and/or the electrical isolation provided by guard ring structure 220 to TSV 200, height h1 is at least 50% of height H2 (i.e., h1≥0.5*H2). In some embodiments, height h1 is about 75% to about 95% of height H2 (i.e., 0.95*H2≥h1≥0.75*H2). Further, since height h1 is less than height H2, primary guard ring 220A includes a gap 222 along height H2 (a total height of guard ring structure). In the depicted embodiment, gap 222 is between an end of primary guard ring 220A (e.g., a bottom thereof formed by metal line(s) 142 in M(X−1) level) and the metal landing pad for TSV 200 (e.g., a respective metal line 142 of MX level). A height h2 of gap 222 is less than height h1, and a sum of height h1 and height h2 is equal to height H2. In some embodiments, height h2 is about 5% to about 25% of height H2 (i.e., 0.25*H2≥h2≥0.05*H2).

Gap 222 corresponds with a portion of the sidewall of TSV 200 that is not overlapped by primary guard ring 220A. For example, in FIG. 3, gap 222 is in VX level, such that primary guard ring 220A is not between metal vias 144 of VX level of FMLI-1 structure and portions of the sidewall of TSV 200 disposed therein. Since guard ring structure 220 is often fabricated before TSV 200 (e.g., in conjunction with FMLI-1 structure and BMLI-1 structure), the present disclosure recognizes that gap 222 may present TSV fabrication challenges. For example, TSV fabrication may include performing an etching process to remove a portion of insulation layer 140-1 to form a TSV opening that exposes the metal landing pad for TSV 200 (e.g., a respective metal line 142 of MX level). During the etching process, moisture from the ambient environment may be introduced into the TSV opening and undesirably diffuse into and/or interact with insulation layer 140-1 (e.g., ILD layers 150 and/or ESLs 152 thereof) and/or metal lines 142/metal vias 144 of FMLI-1 structure disposed therein. The present disclosure recognizes that such moisture may diffuse and/or migrate from the TSV opening through gap 222 to attack low-k dielectric materials (e.g., ILD layers 150) and/or metal materials (e.g., barriers/liners of metal lines 142 and/or metal vias 144) of FMLI-1 structure. In some instances, the moisture may degrade barriers/liners of metal lines 142 and/or metal vias 144, such as that of the metal landing pad for TSV 200, which may induce metal nodule formation (e.g., copper nodules). Such degradation of the low-k dielectric materials and/or the metal materials may degrade device reliability and/or device performance. For example, damaged barriers/liners of metal lines 142/metal vias 144 may result in undesired electromigration and/or insufficient time-dependent dielectric breakdown characteristics in devices associated therewith.

To remedy such challenges, the present disclosure provides a dual guard ring structure that includes a primary guard ring and a secondary guard ring that overlaps any gaps in the primary guard ring. For example, in FIG. 3, secondary guard ring 220B is configured to overlap gap 222 of primary guard ring 220A, such that guard ring structure 220 overlaps the sidewall of TSV 200 along an entire height of guard ring structure 220 (i.e., height H2). Accordingly, secondary guard ring 220B overlaps the portion of the sidewall of TSV 200 in FMLI-1 structure that is not overlapped by primary guard ring 220A, secondary guard ring 220B is disposed between the sidewall of TSV 200 and metal vias 144 in VX level, and secondary guard ring 220B may prevent moisture from diffusing and/or migrating into FMLI-1 structure (e.g., through gap 222 at VX level) during fabrication of TSV 200. Secondary guard ring 220B has a height h3 (e.g., along the z-direction), and height h3 is less than height H2. Since secondary guard ring 220B is configured to “plug” any gaps in primary guard ring 220A (and thus prevent out diffusion and/or migration of moisture through gap 222), height h3 is at least equal to height h2 (i.e., h3≥h2), and a sum of height h3 and height h1 is at least equal to height H2 (i.e., (h3+h1)≥H2). In the depicted embodiment, height h3 is greater than height h2 to ensure sufficient overlap and/or “plugging” of gap 222, and the sum of height h3 and height h1 is greater than height H2 (i.e., (h3+h1)>H2). In such embodiments, secondary guard ring 220B overlaps primary guard ring 220A, such as a portion thereof in M(X−1) level, and secondary guard ring 220B is further disposed between the sidewall of TSV 200 and metal lines 142 of FMLI-1 structure in M(X−1) level. In some embodiments, height h3 is less than 50% of height H2, such as about 10% to about 35% of height H2 (i.e., 0.35*H2≥h3≥0.10*H2). Further, since height h3 is less than height H2, secondary guard ring 220B also includes a gap 224 along height H2. Gap 224 (of secondary guard ring 220B) does not overlap gap 222 (of primary guard ring 220A) to ensure sidewall coverage of TSV 200. In the depicted embodiment, gap 224 is between an end of secondary guard ring 220B (e.g., a top thereof formed by metal line(s) 142 in M(X−1) level) and a top of BMLI-1 structure (e.g., a top thereof formed by BM2 level). A height of gap 224 is less than height h1, and a sum of height h3 and the height of gap 224 (e.g., along the z-direction) may be equal to height H2.

Secondary guard ring 220B is separate and discrete from primary guard ring 220A. In other words, though secondary guard ring 220B may overlap primary guard ring 220A, secondary guard ring 220B is not connected to primary guard ring 220A. Instead, secondary guard ring 220B is positioned laterally adjacent to primary guard ring 220A, and a spacing S (e.g., along the x-direction and/or the y-direction) is between secondary guard ring 220B and primary guard ring 220A. In some embodiments, guard ring-to-guard ring spacing (i.e., spacing S) is about 0.5 to about 5 times a width of metal lines 142/metal lines 142′ of secondary guard ring 220B and/or primary guard ring 220A. For example, metal lines 142/metal lines 142′ of primary guard ring 220A may have a width W1, and spacing S may be about 50% to about 500% of width W1 (i.e., 5*W1≥S≥0.50*W1). In another example, metal lines 142/metal lines 142′ of secondary guard ring 220B may have a width W2, and spacing S may be about 50% to about 500% of width W2 (i.e., 5*W2≥S≥0.50*W2). In some embodiments, width W1 is different than width W2. In some embodiments, width W1 is the same as width W2. In some embodiments, such as depicted, no other metal features (e.g., metal lines 142 and/or metal vias 144) are disposed between secondary guard ring 220B and primary guard ring 220A.

Guard ring structure 220 thus overlaps the sidewall of TSV 200 along an entire height of guard ring structure 220 (i.e., height H2) by using separate and discrete guard ring segments (i.e., secondary guard ring 220B and primary guard ring 220A), instead of implementing a single guard ring (e.g., primary guard ring 220A) that extends to the TSV landing pad (e.g., configuring height h1 to equal height H2 so that the single, primary guard ring does not include any gaps along height H2). Though a single, primary guard ring to the TSV landing pad may prevent moisture penetration, the present disclosure recognizes that connecting a single, primary guard ring to the TSV landing pad may lead to device shock and/or plasma-induced damage (e.g., plasma may attack devices of device layer DL1 during fabrication of stacked chip structure 100), whereas the disclosed dual guard ring configuration may also effectively prevent moisture penetration (e.g., by overlapping any gaps 222 of primary guard ring 220A with secondary guard ring 220B) without the device shock and/or plasma-induced damage risks.

In some embodiments, such as depicted in FIG. 3, primary guard ring 220A and secondary guard ring 220B are configured as an inner guard ring and an outer guard ring, respectively, of guard ring structure 220. In such embodiments, guard ring structure 220 may be referred to as a dual guard ring structure having an outer secondary guard ring (OGR). In some embodiments, such as depicted in FIG. 11, primary guard ring 220A and secondary guard ring 220B switch positions, and primary guard ring 220A and secondary guard ring 220B are configured as an outer guard ring and an inner guard ring, respectively, of guard ring structure 220. In such embodiments, guard ring structure 220 may be referred to as a dual guard ring structure having an inner secondary guard ring (IGR). In such embodiments, widths of the TSV metal landing pad on one or both sides of TSV 200 and/or contact via(s) 210 thereof may be reduced to improve backside contact via overlay. For example, reducing the widths may reduce metal density of the TSV metal landing pad, which may further reduce and/or minimize local stress associated therewith, thereby improving overlay accuracy. In some embodiments, a width W4 (in FIG. 11) of the TSV metal landing pad (e.g., respective metal line 142 of MX level) on either side of TSV 200 and/or contact via(s) 210 thereof may be less than a width W3 (in FIG. 3) of the TSV metal landing pad on either side of TSV 200 and/or contact via(s) 210 thereof. It is further noted that, in FIG. 3, both primary guard ring 220A and secondary guard ring 220B are completely disposed over and overlap the TSV metal landing pad. In contrast, in FIG. 11, secondary guard ring 220B is completely disposed over and overlaps the TSV landing pad, while primary guard ring 220A is partially disposed over the TSV metal landing pad, and primary guard ring 220A overhangs the TSV metal landing pad. In some embodiments, primary guard ring 220A may not be disposed over and/or overlap the TSV metal landing pad.

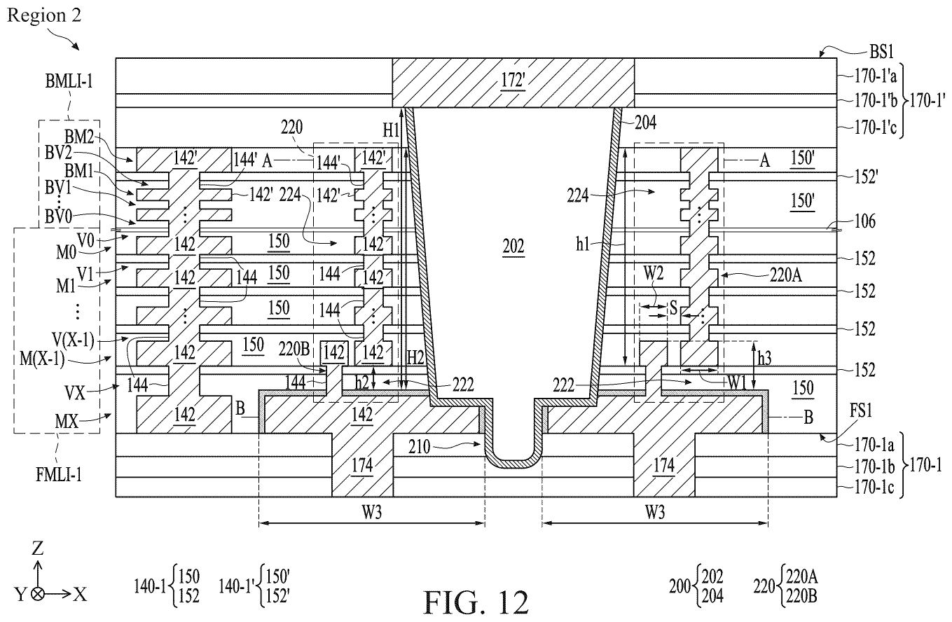

In some embodiments, instead of primary guard ring 220A being disposed within secondary guard ring 220B (FIG. 3) or secondary guard ring 220B being disposed within primary guard ring 220A (FIG. 11), primary guard ring 220A and secondary guard ring 220B may be staggered (e.g., FIG. 12). In such embodiments, such as depicted in FIG. 12, primary guard ring 220A and secondary guard ring 220B may have opposite positioning on opposite sides of TSV 200. For example, primary guard ring 220A forms an inner guard ring on a left side of TSV 200 and an outer guard ring on a right side of TSV 200, while secondary guard ring 220B forms an outer guard ring on the left side of TSV 200 and an inner guard ring on the right side of TSV 200. In such embodiments, guard ring structure 220 may be referred to as a dual guard ring (DGR) structure having an outer secondary guard ring and an inner secondary guard ring (DGR, OGR+IGR). In some embodiments, such configuration may be switched and guard ring structure 220 may be referred to as a dual guard ring structure having an inner secondary guard ring and an outer secondary guard ring (DGR, IGR+OGR).

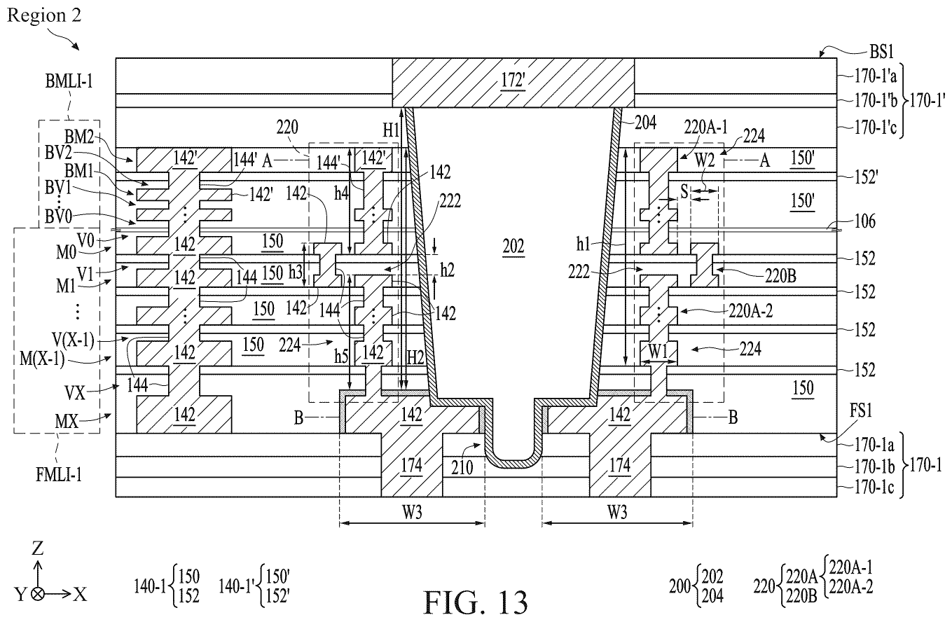

In some embodiments, such as depicted in FIG. 13, gap 222 may be disposed within primary guard ring 220A, instead of between an end of primary guard ring 220A and the TSV metal landing pad (FIG. 3), and gap 222 may be formed at any level of FMLI-1 structure and/or BMLI-1 structure. For example, gap 222 may be formed within primary guard ring 220A at V1 level of FMLI-1 structure. In such example, primary guard ring 220A includes a primary guard ring segment 220A-1, a primary guard ring segment 220A-2, and gap 222 between primary guard ring segment 220A-1 and primary guard ring segment 220A-2. Primary guard ring segment 220A-1 is disposed in BMLI-1 structure, FMLI-1 structure, and device layer DL1, and primary guard ring segment 220A-1 extends from BM2 level to BV0 level, through device layer DL1, and from V0 level to M0 level. Primary guard ring segment 220A-2 is disposed in FMLI-1 structure, primary guard ring segment 220A-2 extends from M1 level to VX level, and primary guard ring segment 220A-2 is disposed on and abuts the TSV metal landing pad (e.g., the respective metal line 142 of MX level). Primary guard ring segment 220A-1 has a height h4 (e.g., along the z-direction), primary guard ring segment 220A-2 has a height h5 (e.g., along the z-direction), and a sum of height h4 and height h5 is equal to height h1. In furtherance of such example, secondary guard ring 220B is disposed in FMLI-1 structure and floats above the TSV metal landing pad, and secondary guard ring 220B overlaps gap 222 within primary guard ring 220A. In the depicted embodiment, height h3 is greater than height h2, and secondary guard ring 220B extends from M0 level to M1 level, thereby overlapping primary guard ring segment 220A-1 at M0 level and overlapping primary guard ring segment 220A-2 at M1 level. In such embodiments, guard ring structure 220 may be referred to as a dual guard ring structure having an outer switchable/selectable secondary guard ring (DGR, O+SGR), and placement of gap 222 within primary guard ring 220A (e.g., what level/layer thereof) and switchable positioning of secondary guard ring 220B based thereon may provide flexible stress management.

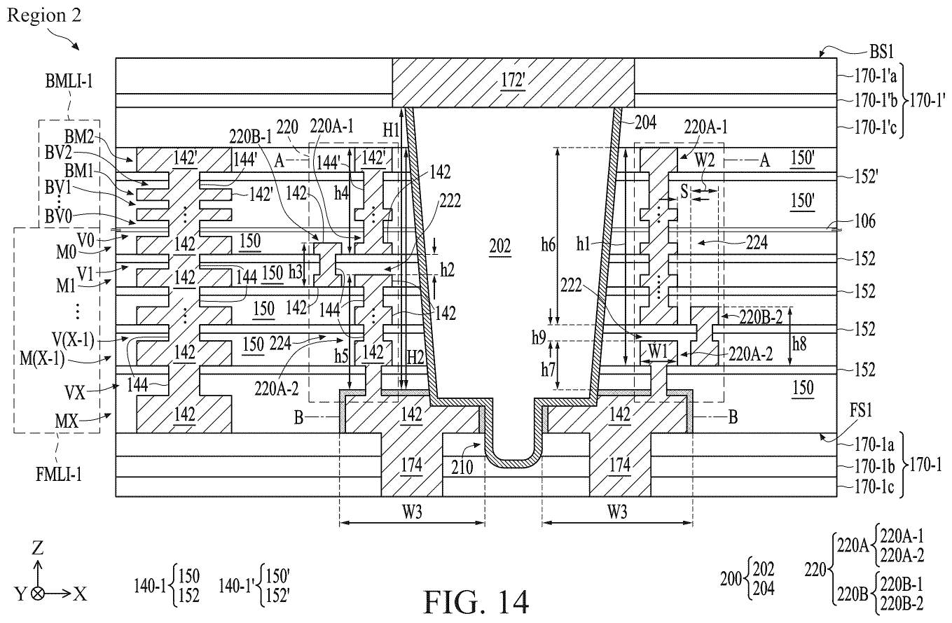

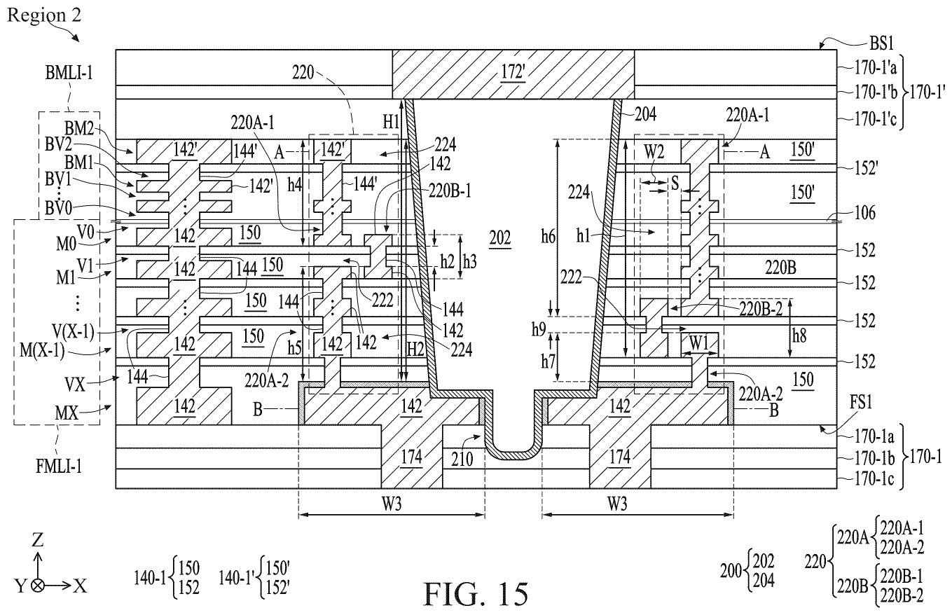

In some embodiments, such as depicted in FIG. 14, primary guard ring 220A may include gaps 222 positioned at different heights, and secondary guard ring 220B may include segments positioned at different heights based on heights of gaps 222. For example, on the left side of TSV 200, a first one of gaps 222 may be formed within primary guard ring 220A at V1 level of FMLI-1 structure between primary guard ring segment 220A-1 and primary guard ring segment 220A-2; and on a right side of TSV 200, a second one of gaps 222 may be formed within primary guard ring 220A at V(X−1) level of FMLI-1 structure between primary guard ring segment 220A-1 and primary guard ring segment 220A-2. In such example, on the left side of TSV 200, primary guard ring 220A may be configured similar to primary guard ring 220A in FIG. 13 (e.g., primary guard ring segment 220A-1 has height h4 and extends from BM2 level to BV0 level, through device layer DL1, and from V0 level to M0 level; primary guard ring segment 220A-2 has height h5 and extends from M1 level to VX level; and primary guard ring segment 220A-2 abuts the TSV metal landing pad). In contrast, on the right, opposite side of TSV 200, primary guard ring 220A has a different configuration. For example, primary guard ring segment 220A-1 extends from BM2 level to BV0 level, through device layer DL1, and from V0 level to M(X−2) level, instead of M0 level, and primary guard ring segment 220A-2 extends from M(X−1) level, instead of M1 level, to VX level. Primary guard ring segment 220A-1 and primary guard ring segment 220A-2 thus have different heights on the right side of TSV 200, such as a height h6 (e.g., along the z-direction) and a height h7 (e.g., along the z-direction), respectively. In some embodiments, a sum of height h6 and height h7 is equal to a sum of height h4 and height h5. In some embodiments, a sum of height h6 and height h7 is different than a sum of height h4 and height h5, such as where gaps 222 have different heights.

In furtherance of such example, because gaps 222 are at different heights, secondary guard ring 220B includes a secondary guard ring segment 220B-1 and a secondary guard ring segment 220B-2. Secondary guard ring segment 220B-1 and secondary guard ring segment 220B-2 are both disposed in FMLI-1 structure and float above the TSV metal landing pad. Secondary guard ring segment 220B-1 is disposed on the left side of TSV 200 and may be configured similar to secondary guard ring 220B in FIG. 13 (e.g., secondary guard ring segment 220B-1 has height h3 and extends from M0 level to M1 level, such that secondary guard ring segment 220B-1 overlaps gap 222 at V1 level, primary guard ring segment 220A-1 at M0 level, and primary guard ring segment 220A-2 at M1 level). Secondary guard ring segment 220B-2 is disposed on the right side of TSV 200, and secondary guard ring segment 220B-2 is disposed at a different height than secondary guard ring segment 220B-1. For example, secondary guard ring segment 220B-2 extends from M(X−2) level to M(X−1) level, such that secondary guard ring segment 220B-2 overlaps gap 222 at V(X−1) level, primary guard ring segment 220A-1 at M(X−2) level, and primary guard ring segment 220A-2 at M(X−1) level. Secondary guard ring segment 220B-2 has a height h8 (e.g., along the z-direction), which may be the same or different than height h3, and gap 222 on the right side of TSV 200 has a height h9 (e.g., along the z-direction), which may be the same or different than height h2.

In the embodiments depicted in FIG. 13 and FIG. 14, secondary guard ring forms an outer guard ring of guard ring structure 220 (i.e., a dual guard ring structure having an outer switchable/selectable secondary guard ring (DGR, O+SGR)). In some embodiments, such as depicted in FIG. 15, primary guard ring 220A and secondary guard ring 220B switch positions, and secondary guard ring 220B is forms an inner guard ring of guard ring structure 220 (i.e., a dual guard ring structure having an inner switchable/selectable secondary guard ring (DGR, I+SGR)). In FIG. 15, primary guard ring 220A may be configured similar to primary guard ring 220A in FIG. 14 and secondary guard ring 220B may be configured similar to secondary guard ring 220B in FIG. 14, except since secondary guard ring 220B is an inner guard ring, secondary guard ring 220B is disposed between TSV 200 and primary guard ring 220A. The present disclosure contemplates various configurations of primary guard ring 220A, secondary guard ring 220B, and gaps 222 to provide various configurations of guard ring structure 220.

Referring again to FIG. 1A, FIG. 1B, FIG. 3, and FIG. 4, TSVs 200 facilitate electrical connections of stacked chip structure 100. For example, referring to FIG. 1B, via PATH A, left-side TSV 200 may electrically connect chip 102 and chip 104, chip 102 to external devices, chip 104 to external devices, or combinations thereof. In some embodiments, left-side TSV 200 is electrically coupled to respective connector 194 via RDL-1 structure (e.g., respective metal line 182 and respective metal vias 184 thereof) and BC-1 structure (e.g., respective metal line 172′ thereof), and left-side TSV 200 is further electrically coupled to device layer DL2 of chip 104 via FMLI-1 structure (e.g., TSV metal landing pad provided by respective metal line 142 thereof), TC-1 structure (e.g., respective metal vias 174 and metal line 172 thereof), bonding structure 160, RDL-2 structure (e.g., respective metal line 186 and respective metal vias 188 thereof), and BMLI-2 structure (e.g., respective metal lines 146′ and respective metal vias 148′ thereof). In such embodiments, electrical coupling of FMLI-1 structure to TC-1 structure facilitates an electrical pathway to flow from chip 102 to chip 104. In some embodiments, left-side TSV 200 may be connected to a power supply source via its respective connector 194, which may be connected to chip 104 via PATH A, in some embodiments.

Further, via PATH B, right-side TSV 200 may electrically connect chip 102 to external devices. In some embodiments, right-side TSV 200 is electrically coupled to respective connector 194 via RDL-1 structure (e.g., respective metal line 182 and respective metal vias 184 thereof) and BC-1 structure (e.g., respective metal line 172′ thereof), and right-side TSV 200 is further electrically coupled to device layer DL1 of chip 102 via FMLI-1 structure (e.g., TSV metal landing pad provided by respective metal line 142 thereof and respective metal lines 142 and metal vias 144 thereof). In such embodiments, since electrical coupling of FMLI-1 structure to TC-1 structure is not provided (e.g., respective metal line 142 of MX level connected to right-side TSV 200 is note connected to a respective metal line 172 of TC-1 structure), TSV 200 facilitates an electrical pathway that flows within chip 102, and such electrical pathway is isolated from chip 104. In some embodiments, right-side TSV 200 may be connected to a power supply source via its respective connector 194, which may be connected to chip 102.

In some embodiments, stacked chip structure 100 is a portion of an advanced three-dimensional integrated circuit (3DIC) package. TSVs 200 of stacked chip structure 100 may be electrically connected to a package substrate, an interposer, a printed circuit board (PCB), a printed wiring board, other packaging structure and/or substrate, or combinations thereof. In some embodiments, TSVs 200 are connected to controlled collapse chip connections (C4 bonds) (e.g., solder bumps and/or solder balls) and/or microbumps (also referred to as microbonds, μbumps, and/or μbonds) (all of which may be provided by connectors 194), which may be connected to a packaging structure.

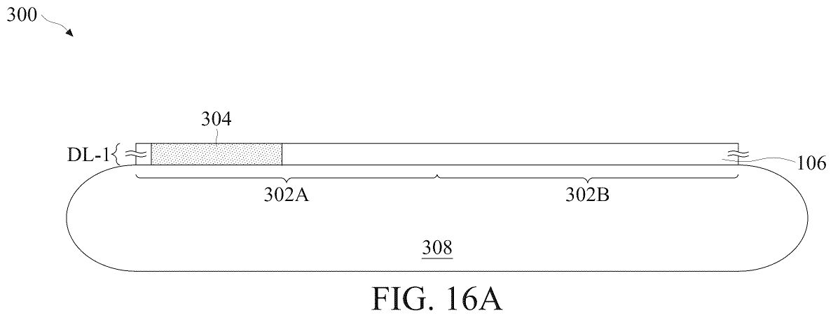

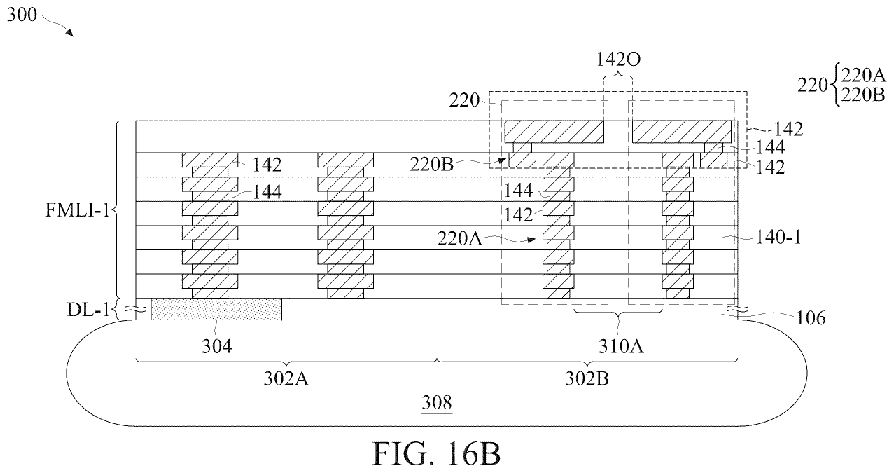

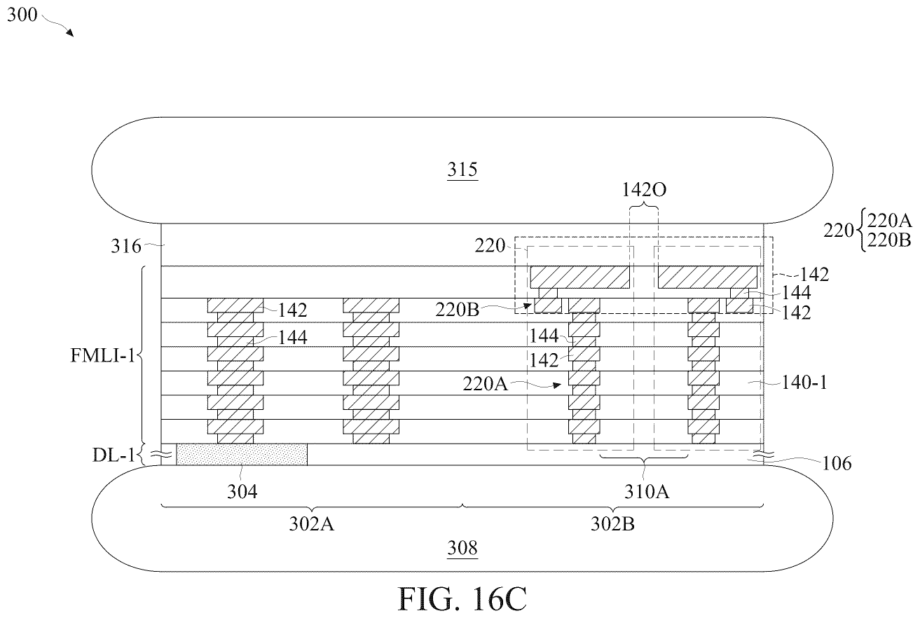

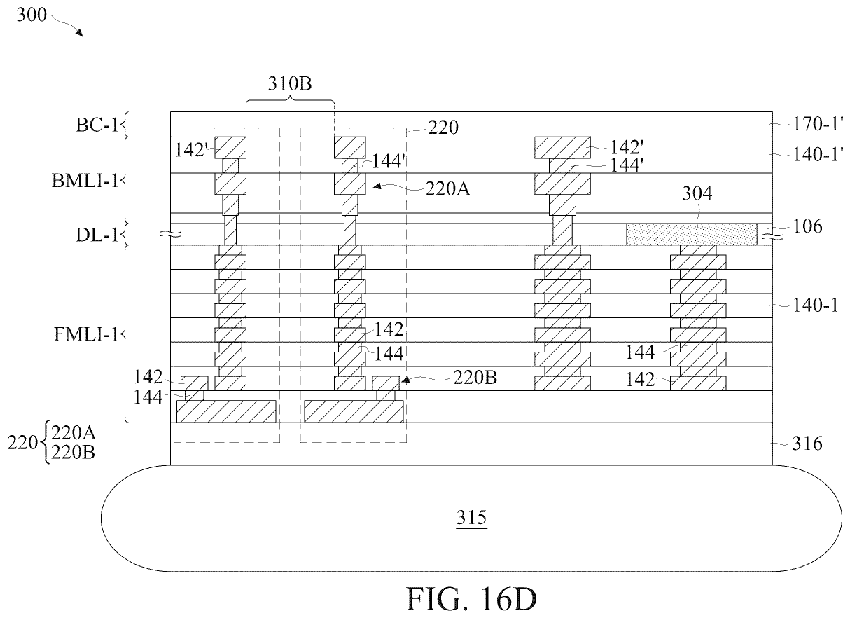

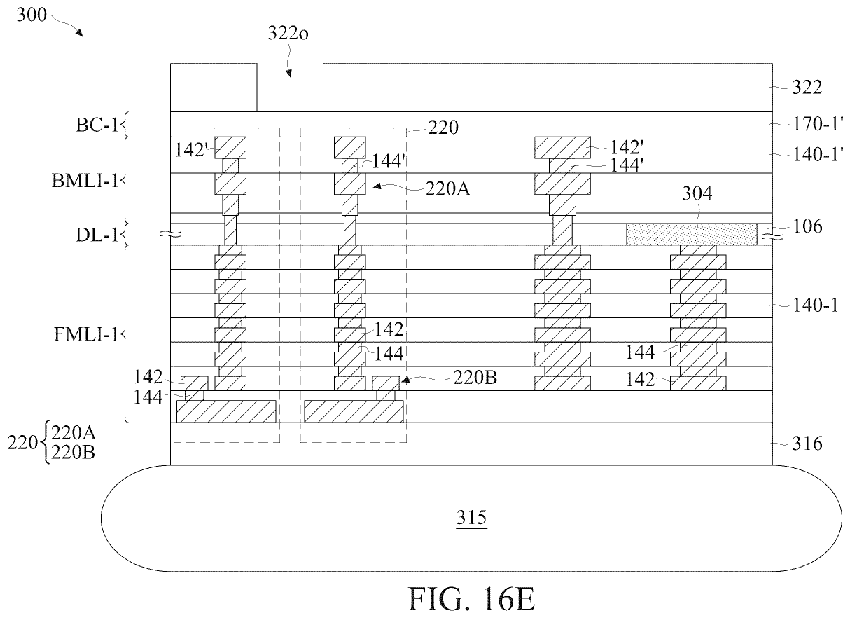

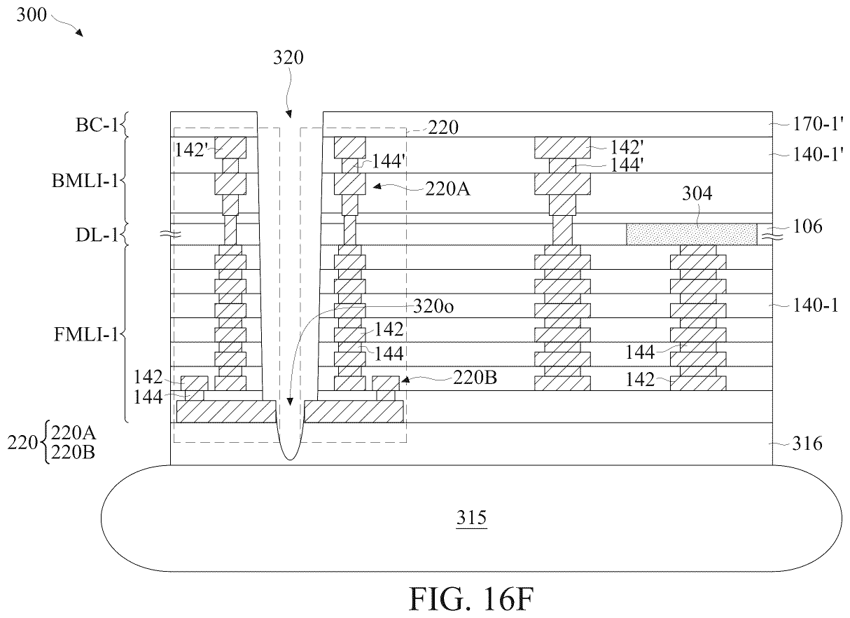

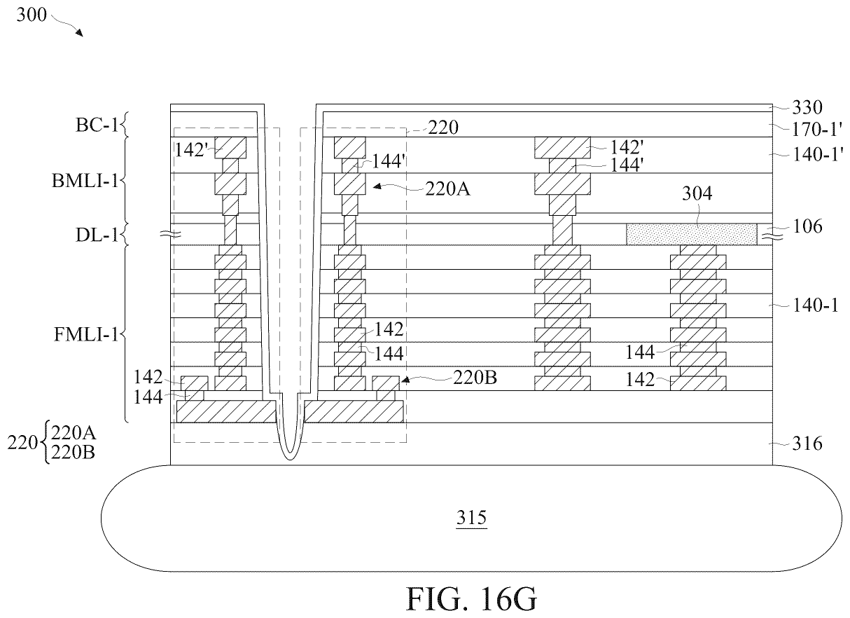

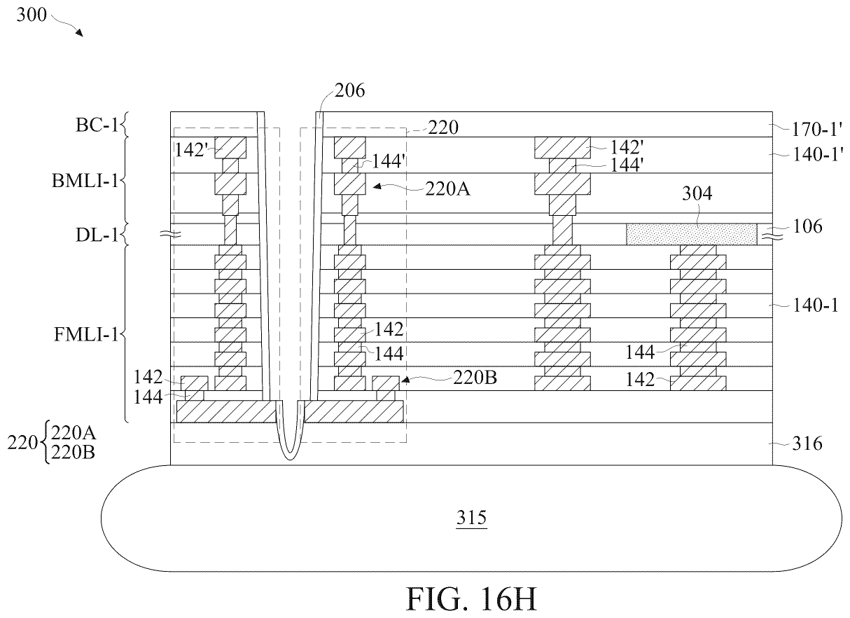

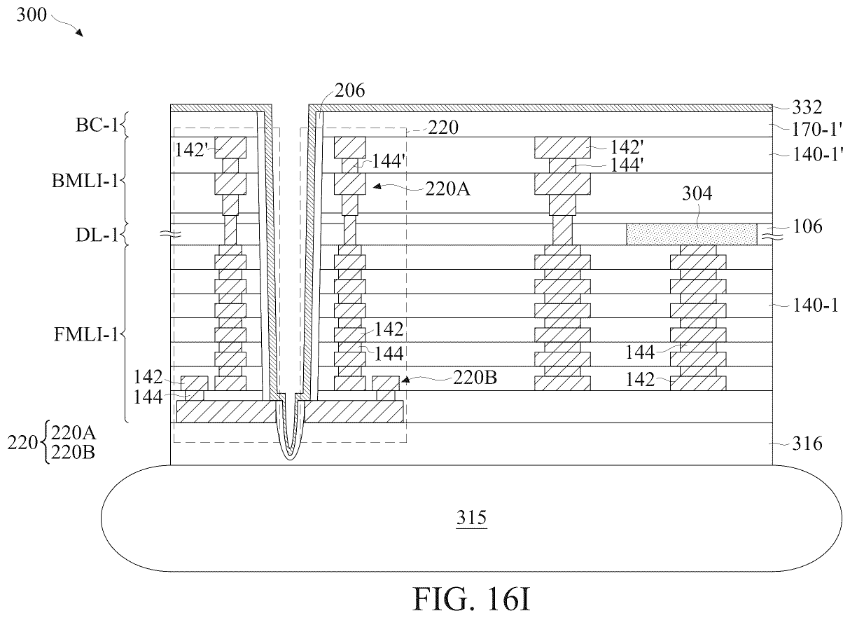

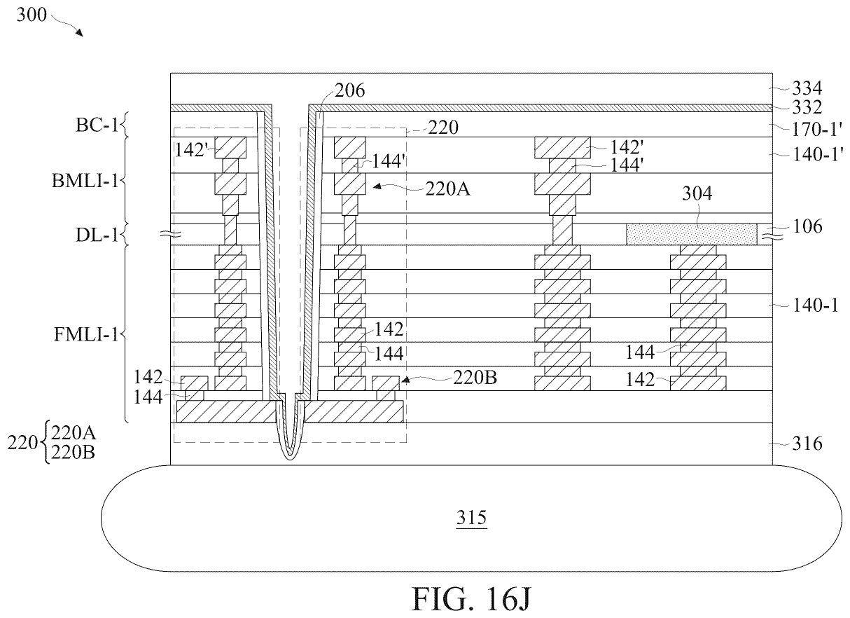

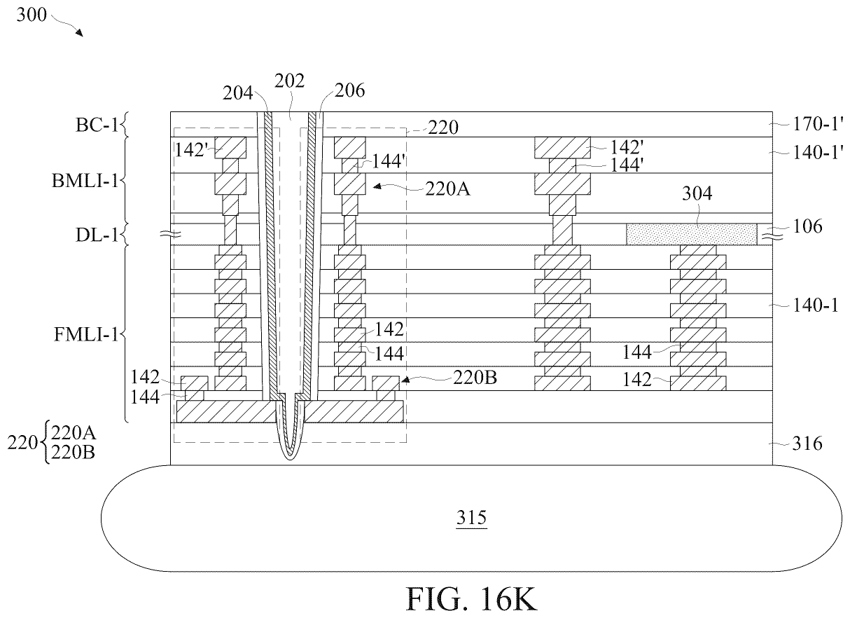

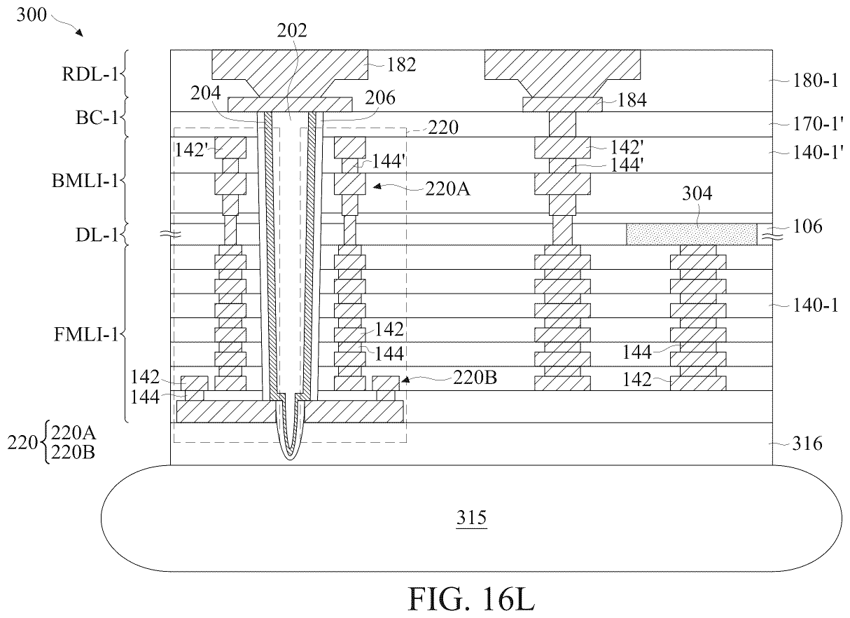

FIGS. 16A-16I are cross-sectional views of a device structure 300, in portion or entirety, at various fabrication stages, including fabrication of a TSV and a guard ring corresponding therewith, according to various aspects of the present disclosure. For ease of description and understanding, the following discussion of FIGS. 16A-16I is directed to fabricating stacked device structure 100, or portion thereof, including fabrication of a respective one of TSVs 200 and its corresponding guard ring structure 220. However, the present disclosure contemplates embodiments where processing associated with FIGS. 16A-16I is implemented to fabricate device structures having different configurations of TSV(s) 200 and/or guard ring(s) 220, such as those described herein. FIGS. 16A-16I have been simplified for the sake of clarity to better understand the inventive concepts of the present disclosure. Additional features can be added in device structure 300, and some of the features described below can be replaced, modified, or eliminated in other embodiments of device structure 300.

Referring to FIG. 16A, after undergoing FEOL processing, device structure 300 includes device layer DL1 having a device region 302A and a TSV region 302B. Device layer DL1 (also referred to as a device substrate) may include one or more devices 304 (e.g., transistors) formed on and/or in substrate 106 in device region 302A. Device layer DL1 may be fabricated on a carrier substrate 308 or attached and/or bonded to carrier substrate 308 after fabrication thereof. Carrier substrate 308 may be a silicon substrate.

Referring to FIG. 16B, device structure 300 may undergo MEOL processing and/or BEOL processing to form FMLI-1 structure (e.g., V0 level to VX level and M0 to MX level) over device layer DL1. For example, insulation layer 140-1 having metal lines 142 and metal vias 144 disposed therein may be formed over device layer DL1 (e.g., over a frontside thereof). FMLI-1 structure may be connected to one or more of devices 304 in device region 302A. Guard ring structure 220, or portion thereof, may be formed over TSV region 302B while forming FMLI-1 structure. For example, a first portion of primary guard ring 220A (e.g., that disposed in FMLI-1 structure) and secondary guard ring 220B may be formed in TSV region 302B, and primary guard ring 220A and/or secondary guard ring 220B may define and/or surround an insulation region 310A of insulation layer 140-1. As described further below, TSV 220 is formed to extend through insulation region 310A. In some embodiments, guard ring structure 220 may connected to a doped region, such as an n-well or a p-well, formed in substrate 106 in TSV region 302B. Further, a TSV landing pad (e.g., metal line 142) may be formed over guard ring structure 220 over TSV region 302B while forming FMLI-1 structure. In some embodiments, such as depicted, the TSV landing pad may be patterned to form a TSV contact via opening (e.g., contact via opening 142O) therein. A lithography process and/or an etching process may be performed to pattern the TSV landing pad. As described below, contact via 210 of TSV 200 may subsequently be formed in contact via opening 142O. In some embodiments, insulation layer 140-1 may fill contact via opening 142O until TSV formation.

Referring to FIG. 16C and FIG. 16D, device structure 300 may undergo additional MEOL processing and/or BEOL processing to form BMLI-1 structure (e.g., BV0 level to BVX′ level and BM0 to BMX′ level) over device layer DL1. For example, insulation layer 140-1′ having metal lines 142′ and metal vias 144′ disposed therein may be formed over device layer DL1 (e.g., over a backside thereof). BMLI-1 structure may be connected to one or more of devices 304 in device region 302A. Guard ring structure 220, or portion thereof, may also be formed over TSV region 302B while forming BMLI-1 structure. For example, a second portion of primary guard ring 220A (e.g., that disposed in BMLI-1 structure) may be formed in TSV region 302B, and any portion of primary guard ring 220A and/or secondary guard ring 220B may further define and/or surround an insulation region 310B of insulation layer 140-1. As described further below, TSV 220 is formed to extend through insulation region 310A. Guard ring structure 220, or portion thereof, may also be formed over TSV region 302B in device layer DL1, such that a portion of guard ring structure 220 may extend through device layer DL1. In some embodiments, processing associated with FIG. 16C and FIG. 16D may include attaching and/or bonding FMLI-1 structure to a carrier substrate 315 (e.g., a silicon carrier) by a bonding layer/structure 316, removing carrier substrate 308 from device layer DL1 to expose an opposite side thereof (e.g., backside), and forming the BMLI-1 structure over the exposed, opposite side of device layer DL1. Device structure 300 may be flipped over before or after removing carrier substrate 308. In some embodiments, a thinning process may be performed on substrate 106 (e.g., to a reduce a thickness thereof) before forming the BMLI-1 structure. In some embodiments, processing associated with FIG. 16D may include forming additional device features and/or structures, such as a portion of insulation layer 170-1′ of BC-1 structure.

Referring to FIGS. 16E-16K, device structure 300 may undergo processing to form TSV 200. Such processing may include forming a TSV trench 320 in insulation region 310A and insulation region 310B of insulation layer 140-1 and insulation layer 140-1′, respectively. TSV trench 320 extends through insulation layer 140-1′, device layer DL1, and insulation layer 140-1 to the TSV landing pad (e.g., metal line 142). In the depicted embodiment, TSV trench 320 further extends through the TSV landing pad (i.e., by re-opening contact via opening 142O of metal line 142, for example, by removing insulation layer 140-1 therefrom) and into bonding layer/structure 316, and the portion of TSV trench 320 extending into and/or through the TSV landing pad may be referred to as a TSV contact via opening 3200. In some embodiments, forming TSV trench 320 includes forming a patterned mask layer 322 having an opening 3220 therein that overlaps and/or exposes insulation region 310B and/or insulation region 310A (FIG. 16E); etching insulation layer 140-1′, device layer DL1, insulation layer 140-1, or combinations thereof using patterned mask layer 322 as an etch mask (FIG. 16F); and removing patterned mask layer 322 during and/or after formation of TSV trench 320 (FIG. 16F). Patterned mask layer 322 may be formed using a lithography process, which can include resist coating (for example, spin-on coating), soft baking, mask aligning, exposure, post-exposure baking, developing the resist, rinsing, drying (for example, hard baking), other suitable process, or combinations thereof. In some embodiments, patterned mask layer 322 includes a patterned hard mask layer (e.g., a silicon nitride layer). In some embodiments, patterned mask layer 322 includes a patterned resist layer. The etching may be a dry etching process, a wet etching process, other etching process, or combinations thereof. As noted herein, moisture from the ambient environment may be introduced into TSV trench 320 during the etching process and/or subsequent formation steps associated with TSV 200. Guard ring structure 220 is thus provided with a dual guard ring design to prevent and/or block such moisture from diffusing and/or migrating into insulation layer 140-1 and/or insulation layer 140-1′. For example, because secondary guard ring 220B overlaps gap(s) 222 in primary guard ring 220A, guard ring structure 220 is disposed along sidewalls of TSV trench 320 along an entire height of guard ring structure 220 and/or along an entirety of the sidewalls of TSV trench 320, and any moisture that may have migrated into device structure 300 through gap(s) 222 in primary guard ring 200 is blocked and/or prevented from doing so by secondary guard ring 220B. In some embodiments, a Bosch process may be implemented when forming TSV trench 320, such as to extend TSV trench 320 into and/or through device layer DL1 (e.g., substrate 106 thereof).

Such processing may further include forming TSV 200, for example, by filling TSV trench 320 with an electrically conductive material. In some embodiments, filling TSV trench 320 includes depositing an insulating material 330 (e.g., SiN, SiCN, oxide, or the like) over a backside of device structure 300 (e.g., over a backside of device layer DL1) that partially fills TSV trench 320 (FIG. 16G); removing insulating material 330 from a bottom of TSV trench 320 (e.g., that disposed over a top of the TSV landing pad) and a bottom of TSV contact via opening 3200 to ensure sufficient connection and/or abutment of TSV 200 and the TSV landing pad (FIG. 16H); depositing a barrier material 332 (e.g., Ti, TiN, and/or TaN) over insulating material 330 that partially fills TSV trench 320 (FIG. 16I); depositing a bulk electrically conductive material 334 (e.g., Cu) over barrier material 332 that fills a remainder of TSV trench 320 (FIG. 16J); and performing a planarization process (e.g., CMP) that removes excess barrier material 332 and excess bulk electrically conductive material 334 (FIG. 16K), thereby forming barrier 204 and conductive plug 202, respectively, of TSV 200. Insulation layer 140-1′ and/or insulation layer 170-1′ may function as a planarization stop layer, and the planarization process may be performed until reaching insulation layer 140-1′ and/or insulation layer 170-1′.

Referring to FIG. 16I, device structure 300 may undergo additional backside processing, such as additional processing associated with forming BC-1 structure (e.g., insulation layer 170-1′ and metal lines 172′ thereof) and forming RDL-1 structure. Further, device structure 300 may undergo additional processing, such as forming TC-1 structure over FMLI-1 structure (after removing carrier substrate 315 and bonding layer 316 therefrom), attaching and/or bonding TC-1 structure to another chip (e.g., RDL-2 structure thereof) via a bonding structure (e.g., bonding structure 160), and forming connectors 194 (e.g., bump formation).

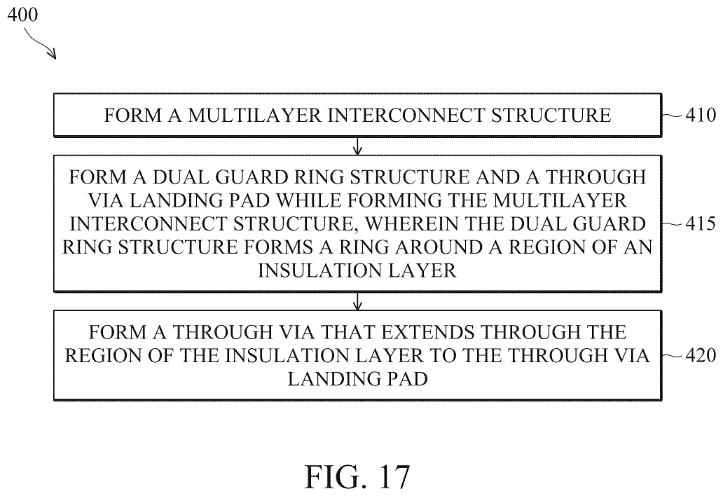

FIG. 17 is a flow chart of a method 400, in portion or entirety, for fabricating a guard ring and a through via, such as guard ring 220 and TSV 200, according to various aspects of the present disclosure. At block 410, method 400 includes forming a multilayer interconnect structure, such as an FMLI structure (e.g., FMLI-1 structure) and/or a BMLI structure (e.g., BMLI-1 structure). The multilayer interconnect structure may be a back-end-of-line (BEOL) structure formed over a device layer/substrate (e.g., device layer DL1), and the BEOL structure may be formed over a frontside of the device layer, a backside of the device layer, or both. At block 415, method 400 includes forming a dual guard ring structure (e.g., guard ring structure 2220) and a through via landing pad (e.g., metal line 142) while forming the multilayer interconnect structure. The dual guard ring structure forms a ring around a region of an insulation layer (e.g., insulation layer 140-1 and/or insulation layer 140-1′). The dual guard ring structure may include a primary guard ring (e.g., primary guard ring 220A) and a secondary guard ring (e.g., secondary guard ring 220B). The secondary guard ring may be adjacent to and discrete from the primary guard ring, and the secondary guard ring may overlap a gap in the primary guard ring. In some embodiments, the through via landing pad is provided with a contact via opening therein (e.g., contact via opening 142O). At block 420, method 400 includes forming a through via (e.g., TSV 200) that extends through the region of the insulation layer to the through via landing pad. The gap in the primary guard ring may correspond with a sidewall portion of the through via that is not overlapped by the primary guard ring. In some embodiments, the through via includes a through contact via (e.g., contact via 210) that is formed in the contact via opening, such that the through via extends into and/or through the through via landing pad. In some embodiments, the multilayer interconnect structure, the dual guard ring structure, and the through via form portions of a first chip, and the first chip may be bonded/attached to a second chip to form a stacked chip structure (e.g., stacked chip structure 100), such as an SoIC. The through via may electrically connect the first chip to the second chip, or the through via may electrically connect external devices/components to the first chip (e.g., to devices, such as transistors of the device layer). FIG. 17 has been simplified for the sake of clarity to better understand the inventive concepts of the present disclosure. Additional steps can be provided before, during, and after method 400, and some of the steps described can be moved, replaced, or eliminated for additional embodiments of method 400.

The present disclosure provides for many different embodiments. An exemplary device structure includes a through via disposed in an insulation layer and a guard ring structure disposed in the insulation layer. The guard ring structure is disposed around the through via. The guard ring structure includes a primary guard ring and a secondary guard ring. The secondary guard ring is adjacent to and discrete from the primary guard ring. The secondary guard ring overlaps a gap in the primary guard ring, and the gap corresponds with a sidewall portion of the through via that is not overlapped by the primary guard ring. In some embodiments, the primary guard ring is a first stack of interconnect structures, and the secondary guard ring is a second stack of interconnect structures. The first stack of interconnect structures and/or the second stack of interconnect structures may be disposed in an FMLI structure, a BMLI structure, a device layer disposed between the FMLI structure and the BMLI structure, other layers/structures of a chip and/or a stacked chip structure (e.g., a TC structure, a BC structure, an RDL structure, other interconnect structure, etc.) or combinations thereof.

In some embodiments, the guard ring structure has a first height, the primary guard ring has a second height less than the first height, and the secondary guard ring has a third height less than the first height. The third height is also less than the second height. In some embodiments, the primary guard ring is an inner guard ring and the secondary guard ring is an outer guard ring. In some embodiments, the primary guard ring is an outer guard ring and the secondary guard ring is an inner guard ring. In some embodiments, on a first side of the through via, the primary guard ring is a first outer guard ring portion and the secondary guard ring is a first inner guard ring portion, and on a second side of the through via that is opposite the first side of the through via, the primary guard ring is a second inner guard ring portion and the secondary guard ring is a second outer guard ring portion.

In some embodiments, the device structure further includes a metal landing pad, the through via abuts the metal landing pad, the secondary guard ring abuts the metal landing pad, and the gap is between an end of the primary guard ring and the metal landing pad. In such embodiments, a height of the secondary guard ring may be greater than a height of the gap between the end of the primary guard ring and the metal landing pad, such that the secondary guard ring overlaps the primary guard ring. In some embodiments, the device structure further includes a metal landing pad, the through via abuts the metal landing pad, the gap is between a first segment of the primary guard ring and a second segment of the primary guard ring, and the first segment of the primary guard ring abuts the metal landing pad. In such embodiments, a height of the secondary guard ring may be greater than a height of the gap between the first segment of the primary guard ring and the second segment of the primary guard ring, such that the secondary guard ring overlaps the first segment of the primary guard ring and the second segment of the primary guard ring.

Another exemplary device structure includes a first chip attached to a second chip and a through via electrically connected to the first chip and the second chip. The through via is disposed in an insulation layer. The device structure further includes a guard ring structure disposed in the insulation layer and around the through via. The guard ring structure includes a primary guard ring and a secondary guard ring. The secondary guard ring is adjacent to and discrete from the primary guard ring. The secondary guard ring overlaps a gap in the primary guard ring and the gap corresponds with a sidewall portion of the through via that is not overlapped by the primary guard ring. In some embodiments, the through via includes a contact via portion that extends into a metal landing pad and the primary guard ring or the secondary guard ring abuts the metal landing pad. In some embodiments, the insulation layer includes a first insulation layer and a second insulation layer of the first chip, and a device layer of the first chip is disposed between the first insulation layer and the second insulation layer. The first insulation layer may be a portion of a frontside multilayer interconnect structure, the second insulation layer may be a portion of backside multilayer interconnect structure, and the through via may extend through the device layer. In such embodiments, the primary guard ring may be disposed in the second insulation layer, the first insulation layer, and the device layer.

In some embodiments, the primary guard ring is disposed within the secondary guard ring and a sum of a first height of the primary guard ring and a second height of the secondary guard ring is greater than or equal to a third height of the guard ring structure, such that the guard ring structure overlaps a sidewall of the through via along an entirety of the third height. In some embodiments, the secondary guard ring is disposed within the primary guard ring and a sum of a first height of the primary guard ring and a second height of the secondary guard ring is greater than or equal to a third height of the guard ring structure, such that the guard ring structure overlaps a sidewall of the through via along an entirety of the third height. In some embodiments, the primary guard ring is staggered relative to the secondary guard ring and a sum of a first height of the primary guard ring and a second height of the secondary guard ring is greater than or equal to a third height of the guard ring structure, such that the guard ring structure overlaps a sidewall of the through via along an entirety of the third height.

An exemplary method includes forming a multilayer interconnect structure and forming a guard ring structure and a through via landing pad while forming the multilayer interconnect structure. The guard ring structure forms a ring around a region of an insulation layer. The guard ring structure includes a primary guard ring and a secondary guard ring. The secondary guard ring is adjacent to the primary guard ring, discrete from the primary guard ring, and overlaps a gap in the primary guard ring. The method further includes forming a through via that extends through the region of the insulation layer to the through via landing pad. The gap in the primary guard ring may correspond with a sidewall portion of the through via that is not overlapped by the primary guard ring.

In some embodiments, the method further includes providing the through via landing pad with a contact via opening therein and forming the through via to include a through contact via in the contact via opening, such that the through via extends into the through via landing pad. In some embodiments, forming the multilayer interconnect structure includes forming a frontside multilayer interconnect structure over a frontside of a device layer and a backside multilayer interconnect structure over a backside of the device layer. In such embodiments, the guard ring structure may be formed while forming the frontside multilayer interconnect structure and the backside multilayer interconnect structure and the through via landing pad may be formed while forming the frontside multilayer interconnect structure.

Another exemplary method includes providing a semiconductor structure that includes a semiconductor substrate, forming an integrated circuit component over a first side of the semiconductor substrate, and forming a first interconnect structure over the integrated circuit component. The method further includes patterning the first interconnect structure to form a first stacked structure (e.g., a primary guard ring) extending partially through the first interconnect structure from a bottom of the interconnect structure towards a top of the first interconnect structure and patterning the first interconnect structure to form a second stacked structure (e.g., a secondary guard ring) adjacent to a portion of the first stacked structure. The second stacked structure may be closer to the top of the first interconnect structure than the first stacked structure, and the first stacked structure and the second stacked structure may be spaced apart and electrically isolated from each other. The method may further include forming a second interconnect structure over a second side of the semiconductor substrate opposite to the first side of the semiconductor substrate. The method may further include patterning the second interconnect structure to form a third stacked structure connected to the first stacked structure in the first interconnect structure. The method may further include forming a through substrate via (TSV) extending through the first interconnect structure and the second interconnect structure. The first stacked structure and the third stacked structure may be laterally aside the TSV.

In some embodiments, the first stacked structure encircles and surrounds the TSV, and the second stacked structure encircles and surrounds the first stacked structure, for example, from a top view of the semiconductor structure. In some embodiments, the method further includes forming a first metallization structure in the first interconnect structure. The first metallization structure, the first stacked structure, and the second stacked structure may be concurrently formed in the first interconnect structure. In some embodiments, the method further includes forming a second metallization structure in the second interconnect structure. The second metallization structure and the third stacked structure may be concurrently formed in the second interconnect structure. In some embodiments, the forming of each of the first stacked structure, the second stacked structure, and the third stacked structure includes forming a first conductive feature, stacking a second conductive feature over the first conductive feature, and overlapping the first conductive feature. The first conductive feature and the second conductive feature may be vertically aligned with each other. In some embodiments, the method further includes patterning the first interconnect structure to form a fourth stacked structure. The fourth stacked structure may be spaced apart from the first stacked structure and the second stacked structure in a first direction, and the fourth stacked structure may partially overlap the first stacked structure and the second stacked structure in a second direction. The second direction may be substantially perpendicular to the first direction, in some embodiments.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device structure comprising:
a through via disposed in an insulation layer; and
a guard ring structure disposed in the insulation layer, wherein the guard ring structure is disposed around the through via and the guard ring structure includes:
a primary guard ring, and
a secondary guard ring adjacent to and discrete from the primary guard ring, wherein the secondary guard ring overlaps a gap in the primary guard ring and the gap corresponds with a sidewall portion of the through via that is not overlapped by the primary guard ring.

2. The device structure of claim 1, wherein:
the guard ring structure has a first height;
the primary guard ring has a second height less than the first height; and
the secondary guard ring has a third height less than the first height, wherein the third height is also less than the second height.

3. The device structure of claim 1, wherein:
the primary guard ring is an inner guard ring; and
the secondary guard ring is an outer guard ring.

4. The device structure of claim 1, wherein:
the primary guard ring is an outer guard ring; and
the secondary guard ring is an inner guard ring.

5. The device structure of claim 1, wherein:
on a first side of the through via, the primary guard ring is a first outer guard ring portion and the secondary guard ring is a first inner guard ring portion; and
on a second side of the through via that is opposite the first side of the through via, the primary guard ring is a second inner guard ring portion and the secondary guard ring is a second outer guard ring portion.

6. The device structure of claim 1, further comprising:
a metal landing pad, wherein the through via abuts the metal landing pad;
the secondary guard ring abuts the metal landing pad; and
the gap is between an end of the primary guard ring and the metal landing pad.

7. The device structure of claim 6, wherein a height of the secondary guard ring is greater than a height of the gap between the end of the primary guard ring and the metal landing pad, such that the secondary guard ring overlaps the primary guard ring.

8. The device structure of claim 1, further comprising:
a metal landing pad, wherein the through via abuts the metal landing pad;
the gap is between a first segment of the primary guard ring and a second segment of the primary guard ring; and
the first segment of the primary guard ring abuts the metal landing pad.

9. The device structure of claim 8, wherein a height of the secondary guard ring is greater than a height of the gap between the first segment of the primary guard ring and the second segment of the primary guard ring, such that the secondary guard ring overlaps the first segment of the primary guard ring and the second segment of the primary guard ring.

10. The device structure of claim 1, wherein:
the primary guard ring is a first stack of interconnect structures; and
the secondary guard ring is a second stack of interconnect structures.

11. A device structure comprising:
a first chip attached to a second chip;
a through via disposed in an insulation layer, wherein the through via is electrically connected to the first chip and the second chip; and
a guard ring structure disposed in the insulation layer and around the through via, wherein the guard ring structure includes:
a primary guard ring, and
a secondary guard ring adjacent to and discrete from the primary guard ring, wherein the secondary guard ring overlaps a first gap in the primary guard ring, the primary guard ring overlaps a second gap in the secondary guard ring, and the first gap is not overlapped by the second gap.

12. The device structure of claim 11, wherein:
the primary guard ring is disposed within the secondary guard ring; and
a sum of a first height of the primary guard ring and a second height of the secondary guard ring is greater than or equal to a third height of the guard ring structure, such that the guard ring structure overlaps a sidewall of the through via along an entirety of the third height.

13. The device structure of claim 11, wherein:
the secondary guard ring is disposed within the primary guard ring; and
a sum of a first height of the primary guard ring and a second height of the secondary guard ring is greater than or equal to a third height of the guard ring structure, such that the guard ring structure overlaps a sidewall of the through via along an entirety of the third height.

14. The device structure of claim 11, wherein:
the primary guard ring is staggered relative to the secondary guard ring; and
a sum of a first height of the primary guard ring and a second height of the secondary guard ring is greater than or equal to a third height of the guard ring structure, such that the guard ring structure overlaps a sidewall of the through via along an entirety of the third height.

15. The device structure of claim 11, wherein:
the through via includes a contact via portion that extends into a metal landing pad; and the primary guard ring or the secondary guard ring abuts the metal landing pad.

16. The device structure of claim 11, wherein:
the insulation layer includes a first insulation layer and a second insulation layer of the first chip, wherein a device layer of the first chip is disposed between the first insulation layer and the second insulation layer, the first insulation layer is a portion of a frontside multilayer interconnect structure, the second insulation layer is a portion of backside multilayer interconnect structure, and the through via extends through the device layer.

17. The device structure of claim 16, wherein the primary guard ring is disposed in the second insulation layer, the first insulation layer, and the device layer.

18. A method comprising:
forming a multilayer interconnect structure;
forming a guard ring structure and a through via landing pad while forming the multilayer interconnect structure, wherein the forming of the multilayer interconnect structure and the forming of the guard ring structure includes performing a lithography process, an etching process, and a deposition process, wherein the guard ring structure forms a ring around a region of an insulation layer and the guard ring structure includes:
a primary guard ring, and
a secondary guard ring adjacent to the primary guard ring, discrete from the primary guard ring, and overlapping a gap in the primary guard ring; and
forming a through via that extends through the region of the insulation layer to the through via landing pad, wherein the gap in the primary guard ring corresponds with a sidewall portion of the through via that is not overlapped by the primary guard ring.

19. The method of claim 18, further comprising:
providing the through via landing pad with a contact via opening therein; and
forming the through via to include a through contact via in the contact via opening, such that the through via extends into the through via landing pad.

20. The method of claim 19, wherein the forming the multilayer interconnect structure includes forming a frontside multilayer interconnect structure over a frontside of a device layer and a backside multilayer interconnect structure over a backside of the device layer, wherein the guard ring structure is formed while forming the frontside multilayer interconnect structure and the backside multilayer interconnect structure and the through via landing pad is formed while forming the frontside multilayer interconnect structure.
